(19) United States
(12) Patent Application Publication
(10) Pub. No.: US 2025/0338732 A1
(43) Pub. Date: Oct. 30, 2025

(54) DISPLAY DEVICE AND WEARABLE DEVICE

(71) Applicant: Samsung Display Co., LTD., Yongin-si (KR)

(72) Inventors: Jung Ki SHIN, Yongin-si (KR); Gun Shik KIM, Yongin-si (KR); Jang Woo KIM, Yongin-si (KR); Seung Man BAEK, Yongin-si (KR)

(21) Appl. No.: 18/987,606

(22) Filed: Dec. 19, 2024

(30) Foreign Application Priority Data
Apr. 25, 2024 (KR) 10-2024-0055253

(51) Int. Cl. H10K 59/131; G02B 27/01; H10K 59/88

(52) U.S. Cl. CPC H10K 59/131; G02B 27/0172; H10K 59/88

(57) ABSTRACT

A display device includes: a substrate including a non-display area and a display area; sub-pixels in the display area; and metal lines crossing the non-display area and the display area in a first direction, wherein each of the metal lines does not overlap, in a plan view, light emitting areas of the sub-pixels, each of the metal lines includes metal patterns protruding in a direction crossing the first direction, and each of the metal lines further includes dummy patterns protruding from the metal patterns.

### CROSS-REFERENCE TO RELATED APPLICATION

The present application claims priority to and the benefit of Korean Patent Application No. 10-2024-0055253 filed in the Korean Intellectual Property Office on Apr. 25, 2024, the entire disclosure of which is incorporated herein by reference.

### BACKGROUND

### 1. Field

Aspects of some embodiments of the present disclosure relate to a display device and a wearable device.

### 2. Description of the Related Art

As information technology develops, the importance of display devices, which provide a connection medium between users and information, is emerging. Accordingly, the use of display devices such as liquid crystal display devices, organic light emitting display devices, and the like has been increasing.

The display device displays images using pixels. In order to implement augmented reality (AR), virtual reality (VR), and mixed reality (MR), the display device may desirably have a relatively large number of pixels located on a small display surface.

As the gap between pixels narrows, a leakage current through a common layer of adjacent pixels may become a problem.

The above information disclosed in this Background section is only for enhancement of understanding of the background and therefore the information discussed in this Background section does not necessarily constitute prior art.

### SUMMARY

Aspects of some embodiments of the present disclosure include a display device and a wearable device that may a prevent or reduce leakage current through a common layer between adjacent pixels.

According to some embodiments of the present disclosure, a display device includes: a substrate including a non-display area and a display area; sub-pixels in the display area; and metal lines crossing the non-display area and the display area in a first direction, wherein each of the metal lines does not overlap, in a plan view, light emitting areas of the sub-pixels, each of the metal lines includes metal patterns protruding in a direction crossing the first direction, and each of the metal lines further includes dummy patterns protruding from the metal patterns.

According to some embodiments, widths of the dummy patterns in the first direction may be smaller than widths of the metal patterns in the first direction.

According to some embodiments, widths of the dummy patterns in the first direction may be the same as widths of the metal patterns in the first direction.

According to some embodiments, widths of the dummy patterns in the first direction may gradually decrease as they protrude in a protruding direction.

According to some embodiments, each of the metal patterns may have a ring shape.

According to some embodiments, each of the dummy patterns may have a line shape.

According to some embodiments, a protruding direction of the metal patterns and a protruding direction of the dummy patterns connected to the metal patterns may be the same.

According to some embodiments, the metal patterns and the dummy patterns may protrude in a second direction crossing the first direction or in a direction opposite to the second direction between the light emitting areas.

According to some embodiments, a metal pattern protruding in the second direction may face an adjacent metal pattern protruding in a direction opposite to the second direction.

According to some embodiments, a dummy pattern protruding in the second direction may face an adjacent dummy pattern protruding in a direction opposite to the second direction.

According to some embodiments, a dummy pattern protruding in the second direction may face an adjacent metal pattern protruding in a direction opposite to the second direction, while it may not face an adjacent dummy pattern connected to the adjacent metal pattern.

According to some embodiments, the metal lines may include first metal lines and second metal lines, the first metal lines and the second metal lines may be alternately arranged in the second direction, and with respect to the second direction, the first metal lines may have a shape symmetrical to the second metal lines.

According to some embodiments, each of the metal patterns of the first metal lines may protrude to face an adjacent metal pattern of an adjacent second metal line.

According to some embodiments, each of the metal lines may further include line patterns connecting the metal patterns.

According to some embodiments, the line patterns may have a shape inclined, in a plan view, to correspond to an outer periphery of the light emitting areas adjacent thereto.

According to some embodiments, the display device may further include a first metal pad in the non-display area; and a second metal pad in the non-display area and in the first direction from the first metal pad.

According to some embodiments, the display area may be between the first metal pad and the second metal pad, and the metal lines may connect the first metal pad and the second metal pad.

According to some embodiments, the display device may further include data lines extending in a second direction crossing the first direction and connected to the sub-pixels; and pads connected to the data lines.

According to some embodiments of the present disclosure, a wearable device includes: a first display panel; and a second display panel, wherein each of the first display panel and the second display panel includes a substrate including a non-display area and a display area; sub-pixels in the display area; and metal lines crossing the non-display area and the display area in a first direction, and each of the metal lines does not overlap, in a plan view, light emitting areas of the sub-pixels, each of the metal lines includes metal patterns protruding in a direction crossing the first direction, and each of the metal lines further includes dummy patterns protruding from the metal patterns.

According to some embodiments, widths of the dummy patterns in the first direction may be smaller than or equal to widths of the metal patterns in the first direction.

According to some embodiments, each of the metal patterns may have a ring shape, and each of the dummy patterns may have a line shape.

According to some embodiments of the present disclosure, in a display device and a wearable device of the present disclosure, it may be possible to prevent or reduce a leakage current through a common layer between adjacent pixels.

### BRIEF DESCRIPTION OF THE DRAWINGS

FIG. 1 illustrates a block diagram of a display device according to some embodiments.

FIG. 2 illustrates a top plan view of a display panel of FIG. 1 according to some embodiments.

FIG. 3 illustrates a block diagram of a sub-pixel.

FIG. 4 is a drawing for explaining a sub-pixel according to some embodiments.

FIG. 5 illustrates an exploded perspective view of a portion of a display panel of FIG. 1.

FIG. 6 illustrates a top plan view of a relationship between sub-pixels and metal lines.

FIG. 7 illustrates a cross-sectional view of a light emitting structure according to some embodiments.

FIG. 8 illustrates a cross-sectional view of a light emitting structure according to some embodiments.

FIG. 9 illustrates a cross-sectional view taken along the line I-I′ of FIG. 6.

FIG. 10 illustrates a cross-sectional view of FIG. 9 according to some embodiments.

FIG. 11 is a drawing for explaining metal lines according to some embodiments.

FIG. 12 is a drawing for explaining a temperature of a metal pattern of a metal line of FIG. 11.

FIG. 13 is a drawing for explaining a temperature of a line pattern of a metal line of FIG. 11.

FIG. 14 illustrates temperature graphs of areas of interest in FIG. 12 and FIG. 13.

FIG. 15 is a drawing for explaining metal lines according to some embodiments.

FIG. 16 is a drawing for explaining a metal pattern and a dummy pattern of the metal line in FIG. 15.

FIG. 17 illustrates temperature graphs of areas of interest in FIG. 12, FIG. 13, and FIG. 16.

FIG. 18 a drawing for explaining various embodiments of dummy patterns.

FIG. 19 illustrates a block diagram of a display system according to some embodiments.

FIG. 20 illustrates a perspective view of an application example of the display system of FIG. 19.

FIG. 21 illustrates a head-mounted display device worn on a user of FIG. 20.

### DETAILED DESCRIPTION

Aspects of some embodiments of the present disclosure will be described more fully hereinafter with reference to the accompanying drawings, in which embodiments of the disclosure are shown. As those skilled in the art would realize, the described embodiments may be modified in various different ways, all without departing from the spirit and scope of embodiments according to the present disclosure.

In order to more clearly describe aspects of some embodiments of the present disclosure, parts or portions that are irrelevant to enable a person having ordinary skill in the art to make, use, or understand embodiments according to the present disclosure may be omitted, and identical or similar constituent elements throughout the specification are denoted by the same reference numerals. Therefore, the above-mentioned reference numerals may be used in other drawings.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc. may be exaggerated for clarity.

In addition, the expression “same” in the description may mean “substantially the same.”

That is, it may be the same enough to convince those skilled in the art to be the same. Even other expressions may be expressions from which “substantially” is omitted.

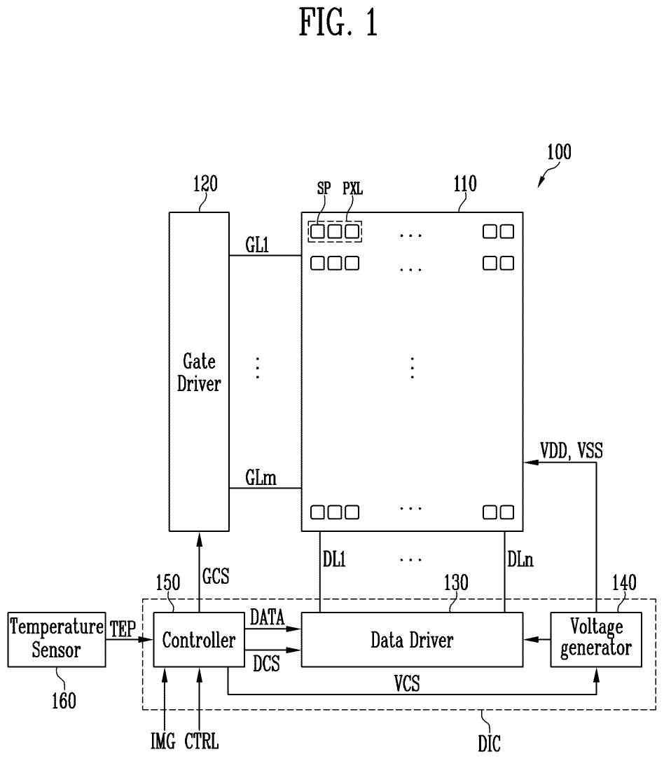

FIG. 1 illustrates a block diagram of a display device according to some embodiments.

Referring to FIG. 1, a display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, the sub-pixels SP may respectively generate light of a specific color, such as red, green, blue, cyan, magenta, yellow, or the like. Two or more of the sub-pixels SP may configure one pixel PXL. For example, as shown in FIG. 1, three sub-pixels may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. According to some embodiments, the gate control signal GCS may include a start signal indicating the start of each frame, a horizontal synchronization signal for outputting gate signals in synchronization with the timing at which data signals are applied, and the like.

The gate driver 120 may be located on one side of the display panel 110. However, embodiments are not limited thereto. For example, the gate driver 120 may be divided into two or more physically and/or logically separated drivers, and the drivers may be located on one side of the display panel 110 and the other side of the display panel 110 opposite to the one side. As described above, the gate driver 120 may be arranged around the display panel 110 in various forms according to the embodiments.

The data driver 130 is connected to the sub-pixels SP arranged in a column direction through the first to n-th data lines DL1 to DLn. The data driver 130 receives image data (DATA) and data control signal DCS from the controller 150. The data driver 130 operates in response to the data control signal DCS. According to some embodiments, the data control signal DCS may include a source start pulse, a source shift clock, a source output enable signal, and the like.

The data driver 130 may use voltages from the voltage generator 140 to apply data signals having grayscale voltages corresponding to the image data (DATA) to the first to n-th data lines DL1 to DLn. When a gate signal is applied to each of the first to m-th gate lines GL1 to GLn, data signals corresponding to the image data DATA may be applied to the data lines DL1 to DLm. Accordingly, the corresponding sub-pixels SP may generate light corresponding to the data signals. Accordingly, images may be displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to constituent elements of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the first power voltage VDD. According to some embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation to sense electrical characteristics of transistors and/or light emitting elements of the sub-pixels SP, a reference voltage (e.g., a set or predetermined reference voltage) may be applied to the first to n-th data lines DL1 to DLn, and the voltage generator 140 may generate the reference voltage.

The controller 150 controls various operations of the display device 100. The controller 150 receives input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. According to some embodiments, the controller 150 may output the image data DATA by aligning the input image data IMG to be suitable for the arrangement of the sub-pixels SP.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. According to some embodiments, at least one of the data driver 130, the voltage generator 140, or the controller 150 may be provided as a component separated from the driver integrated circuit DIC.

According to some embodiments, the display device 100 may include at least one temperature sensor 160. The temperature sensor 160 is configured to sense a surrounding temperature and generate temperature data TEP representing the sensed temperature. According to some embodiments, the temperature sensor 160 may be arranged to be adjacent to the display panel 110 and/or the driver integrated circuit DIC.

The controller 150 may control various operations of the display device 100 in response to the temperature data TEP. According to some embodiments, the controller 150 may adjust the luminance of an image outputted from the display panel 110 in response to the temperature data TEP. For example, the controller 150 may control the data signals and the first and second power voltages VDD and VSS by controlling components such as the data driver 130 and/or the voltage generator 140.

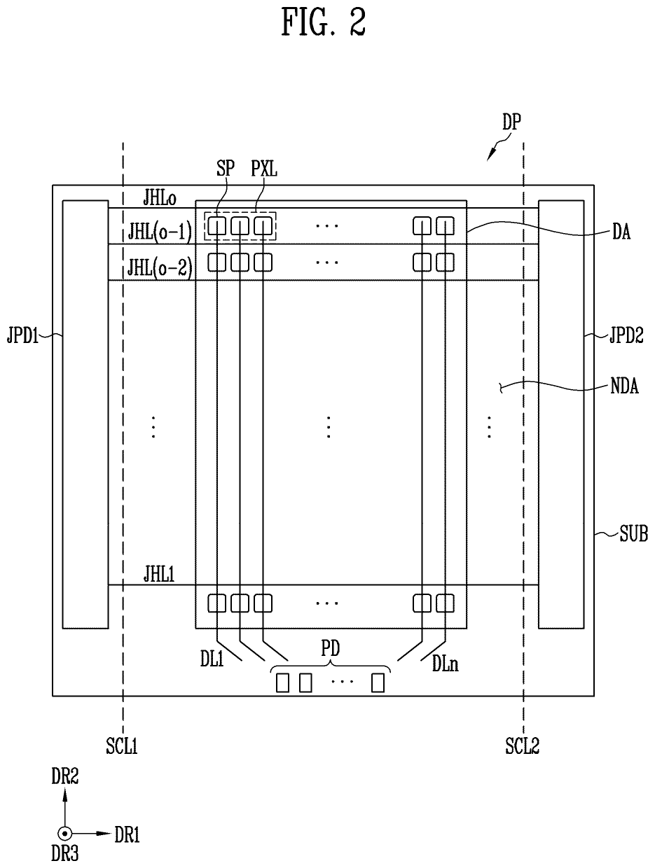

FIG. 2 illustrates a top plan view of a display panel of FIG. 1 according to some embodiments.

Referring to FIG. 2, a DP of the display panel 110 of FIG. 1 may include a display area DA and a non-display area NDA. The display panel DP displays images through the display area DA. The non-display area NDA is arranged around (e.g., in a periphery or outside a footprint of) the display area DA.

The display panel DP may include a substrate SUB, sub-pixels SP, a first metal pad JPD1, a second metal pad JPD2, metal lines JHL1 to JHLo, and pads PD.

When the display panel DP is used as a display screen for a head mounted display (HMD), a virtual reality (VR) device, a mixed reality (MR) device, or an augmented reality (AR) device, the display panel DP may be positioned very close to the user's eyes. In this case, the sub-pixels SP with relatively high integration are required. In order to increase the integration of the sub-pixels SP, the substrate SUB may be provided as a silicon substrate. The sub-pixels SP and/or the display panel DP may be formed on the substrate SUB, which is a silicon substrate. The display device 100 (see FIG. 1) including the display panel DP formed on the substrate SUB, which is a silicon substrate, may be referred to as an OLED on silicon (OLEDoS) display device.

The sub-pixels SP are located in the display area DA on the substrate SUB. The sub-pixels SP may be arranged in a matrix format along a first direction DR1 and a second direction DR2 crossing the first direction DR1. However, embodiments are not limited thereto. For example, the sub-pixels SP may be arranged in a zigzag form along first direction DR1 and second direction DR2. For example, the sub-pixels SP may be arranged in a PENTILE™ shape or arrangement. The first direction DR1 may be a row direction, and the second direction DR2 may be a column direction. Two or more of the plurality of sub-pixels SP may configure one pixel PXL.

The substrate SUB may include the display area DA and the non-display area NDA. A constituent element to control the sub-pixels SP may be located in the non-display area NDA on the substrate SUB. For example, wires connected to the sub-pixels SP, such as the first to m-th gate lines GL1 to GLm and the first to n-th data lines DL1 to DLn of FIG. 1, may be space-efficiently located in the non-display area NDA.

The first metal pad JPD1 may be located in the non-display area NDA. The first metal pad JPD1 may have a substantially rectangular shape with a long side extending in the second direction DR2 and a short side extending in the first direction DR1. A length of the long side may be similar to a length of the display area DA in the second direction DR2. For example, a length of the long side may be greater than or equal to that of the display area DA in the second direction DR2. The first metal pad JPD1 may include at least one or more metallic materials. For example, the first metal pad JPD1 may include a material with high resistivity and a melting point, such as molybdenum (Mo), titanium (Ti), titanium nitride (TiN), and tungsten (W). The first metal pad JPD1 may be arranged in a direction opposite to the first direction DR1 from the display area DA.

The second metal pad JPD2 may be located in the non-display area NDA, and may be arranged in the first direction DR1 from the first metal pad JPD1. The second metal pad JPD2 may have a substantially rectangular shape with a long side extending in the second direction DR2 and a short side extending in the first direction DR1. A length of the long side may be similar to a length of the display area DA in the second direction DR2. For example, a length of the long side may be greater than or equal to that of the display area DA in the second direction DR2. The second metal pad JPD2 may include at least one or more metallic materials. For example, the second metal pad JPD2 may include a material with high resistivity and a melting point, such as molybdenum (Mo), titanium (Ti), titanium nitride (TIN), and tungsten (W). The second metal pad JPD2 may be arranged in the first direction DR1 from the display area DA.

The metal lines JHL1 to JHLo may cross the non-display area NDA and the display area DA in the first direction DR1. The metal lines JHL1 to JHLo may connect the first metal pad JPD1 and the second metal pad JPD2. o may be an integer greater than 1. Each of the metal lines JHL1 to JHLo may extend in the first direction DR1 so as not to overlap with the sub-pixels SP. Here, not overlapping with the sub-pixels SP means not overlapping with the light emitting areas of the sub-pixels SP (e.g., in a plan view, for example, from a direction facing toward a display surface of the display area DA). That is, the metal lines JHL1 to JHLo may extend to be spaced apart from the light emitting areas of the sub-pixels SP in a plan view. The metal lines JHL1 to JHLo may be arranged parallel to each other in the second direction DR2. One ends of the metal lines JHL1 to JHLo may be connected to the first metal pad JPD1, and the other ends of the metal lines JHL1 to JHLo may be connected to the second metal pad JPD2. For example, the metal lines JHL1 to JHLo may include a material with high resistivity and a melting point, such as molybdenum (Mo), titanium (Ti), titanium nitride (TiN), and tungsten (W). The metal lines JHL1 to JHLo, the first metal pad JPD1, and the second metal pad JPD2 may be formed simultaneously by the same process, or may be formed at different times by different processes.

When a first voltage is applied to the first metal pad JPD1 and a second voltage different from the first voltage is applied to the second metal pad JPD2, heat may occur in metal lines JHL1 to JHLo due to Joule heating. Here, the first voltage may be a single pulse or may include a plurality of pulses. Due to the heat generation, an organic material adjacent to the metal lines JHL1 to JHLo may be sublimated. For example, the second voltage may be a low voltage or a ground voltage.

The virtual first cutting line SCL1 may extend in the second direction DR2 between the first metal pad JPD1 and the display area DA. The first cutting line SCL1 may cross the metal lines JHL1 to JHLo. The virtual second cutting line SCL2 may extend in the second direction DR2 between the second metal pad JPD2 and the display area DA. The second cutting line SCL2 may cross the metal lines JHL1 to JHLo.

After the Joule heating process, the display panel DPr is cut along the cutting lines SCL1 and SCL2, so that the first metal pad JPD1 and the second metal pad JPD2 may not exist in the final product. According to some embodiments, by not cutting the display panel DPr along the cutting lines SCL1 and SCL2, the first metal pad JPD1 and the second metal pad JPD2 may exist in the final product.

At least one of the gate driver 120, the data driver 130, the voltage generator 140, the controller 150, or the temperature sensor 160 in FIG. 1 may be integrated in the non-display area NDA of the display panel DP. According to some embodiments, the gate driver 120 of FIG. 1 may be mounted on the display panel DP, and may be located in the non-display area NDA. According to some embodiments, the gate driver 120 may be implemented as an integrated circuit separated from the display panel DP. According to some embodiments, the temperature sensor 160 may be located in the non-display area NDA to detect the temperature of the display panel DP.

The pads PD are located in the non-display area NDA on the substrate SUB. The pads PD may be electrically connected to the sub-pixels SP through wires. For example, the pads PD may be connected to the sub-pixels SP through the first to n-th data lines DL1 to DLn. The first to nth data lines DL1 to DLn may extend in the second direction DR2 and cross the metal lines JHL1 to JHLo.

The pads PD may interface the display panel DP to other constituent elements of the display device 100 (see FIG. 1). According to some embodiments, voltages and signals required for operations of constituent elements included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

According to some embodiments, the circuit board may be electrically connected to the pads PD by using a conductive adhesive member such as an anisotropic conductive film. In this case, the circuit board may be a flexible printed circuit board (FPCB) or a flexible film made of a flexible material. The driver integrated circuit DIC may be mounted on the circuit board to be electrically connected to the pads PD.

According to some embodiments, the display area DA may have various shapes. The display area DA may have a closed-loop shape including sides of a straight line and/or a curved line. For example, the display area DA may have shapes such as a polygonal shape, a circular shape, a semicircular, and an elliptical shape.

According to some embodiments, the display panel DP may have a flat display surface. According to some embodiments, the display panel DP may have a display surface that is at least partially round. According to some embodiments, the display panel DP may be bendable, foldable, or rollable. In these cases, the display panel DP and/or the substrate SUB may include materials with flexible properties.

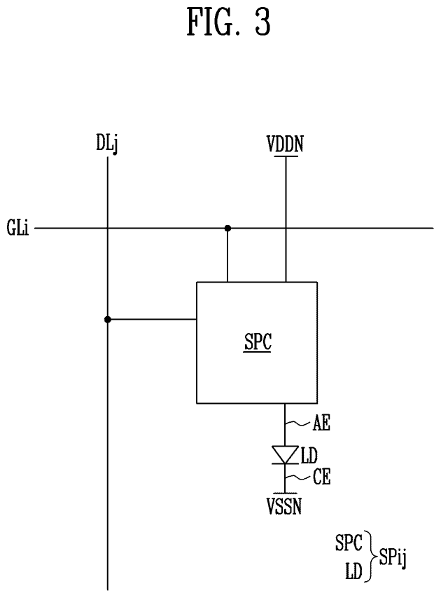

FIG. 3 illustrates a block diagram of a sub-pixel.

Referring to FIG. 3, among the sub-pixels SP, a sub-pixel SPij located in an i-th row (i is an integer greater than or equal to 1 and less than or equal to m) and a j-th column (j is an integer greater than or equal to 1 and less than or equal to n) is illustrated as an example. The sub-pixel SPij may include a sub-pixel circuit SPC and a light emitting element LD.

The light emitting element LD is connected between the first power voltage node VDDN and a second power voltage node VSSN. In this case, the first power voltage node VDDDN is a node that transmits the first power voltage VDD of FIG. 1, and the second power voltage node VSSN is a node that transmits the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi of the first to m-th gate lines GL1 to GLm of FIG. 1 and a j-th data line DLj of the first to n-th data lines DL1 to DLn of FIG. 1. The sub-pixel circuit SPC is configured to control the light emitting element LD according to signals received through these signal lines.

The sub-pixel circuit SPC may operate in response to a gate signal received through the i-th gate line GLi. The sub-pixel circuit SPC may receive a data signal through the j-th data line DLj. For example, the sub-pixel circuit SPC may respond to the gate signal to store a voltage corresponding to the data signal. Based on the voltage stored in the sub-pixel circuit SPC, the light emitting element LD may generate light having a luminance corresponding to the data signal.

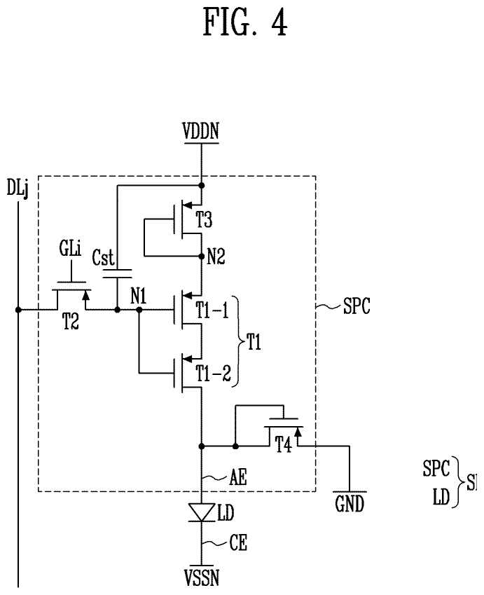

FIG. 4 is a drawing for explaining a sub-pixel according to some embodiments. Although FIG. 4 illustrates various components in a sub-pixel according to some embodiments, embodiments according to the present disclosure are not limited thereto, and according to some embodiments, the sub-pixel may include additional components or fewer components without departing from the spirit and scope of embodiments according to the present disclosure.

Referring to FIG. 4, the sub-pixel SPij may include a sub-pixel circuit SPC and a light emitting element LD. The sub-pixel circuit SPC may include first to fourth transistors T1 to T4 and a storage capacitor Cst.

In the first transistor T1, a gate electrode may be connected to a first node N1, a first electrode may be connected to a second node N2, and a second electrode may be connected to to the anode electrode AE of the light emitting element LD. The first transistor T1 may include sub-transistors T1-1 and T1-2 connected in series. The first transistor T1 may be a driving transistor.

In the second transistor T2, a gate electrode may be connected to the i-th gate line GLi, a first electrode may be connected to the j-th data line DLj, and a second electrode may be connected to the first node N1.

In the third transistor T3, a gate electrode may be connected to the second node N2, a first electrode may be connected to the first power voltage node VDDN, and a second electrode may be connected to the second node N2.

In the fourth transistor T4, a gate electrode and a first electrode may be connected to the anode electrode AE of the light emitting element LD, and a second electrode may receive a reference voltage GND. The reference voltage GND may be set to be smaller than the first power voltage VDD. According to some embodiments, the reference voltage GND may be the same as the second power voltage VSS. According to some embodiments, the reference voltage GND may be different from the second power voltage VSS.

In the storage capacitor Cst, a first electrode may be connected to the first power voltage node VDDN, and a second electrode may be connected to the first node N1.

The light emitting element LD may include the anode electrode AE, the cathode electrode CE, and the light emitting structure. The light emitting structure may be located between the anode electrode AE and the cathode electrode CE.

When a gate signal at a turn-on level (for example, a low level) is applied to the i-th gate line GLi, the second transistor T2 may be turned on. In this case, the data signal applied to the j-th data line DLj may be applied to the first node N1 through the second transistor T2. The storage capacitor Cst may maintain the voltage of the data signal. In response to the voltage of the data signal, the first transistor T1 may determine an amount of a driving current flowing from the first power voltage node VDDN to the second power voltage node VSSN. The light emitting element LD may emit light with luminance corresponding to the amount of the driving current.

The third transistor T3 and the fourth transistor T4 are diode-connected transistors, which may limit the direction of the current so that the current does not flow in the reverse direction. According to some embodiments, the third transistor T3 and the fourth transistor T4 may be removed from the sub-pixel circuit SPC. When the third transistor T3 is removed, the second node N2 may be directly connected to the first power voltage node VDDN.

The first to fourth transistors T1 to T4 may be P-type transistors. Each of the transistors T1 to T4 may be a metal oxide silicon field effect transistor (MOSFET). However, embodiments are not limited thereto. For example, at least one of the transistors T1 to T4 may be replaced with an N-type transistor.

According to some embodiments, the transistors T1 to T6 may include an amorphous silicon semiconductor, a monocrystalline silicon semiconductor, a polycrystalline silicon semiconductor, and an oxide semiconductor.

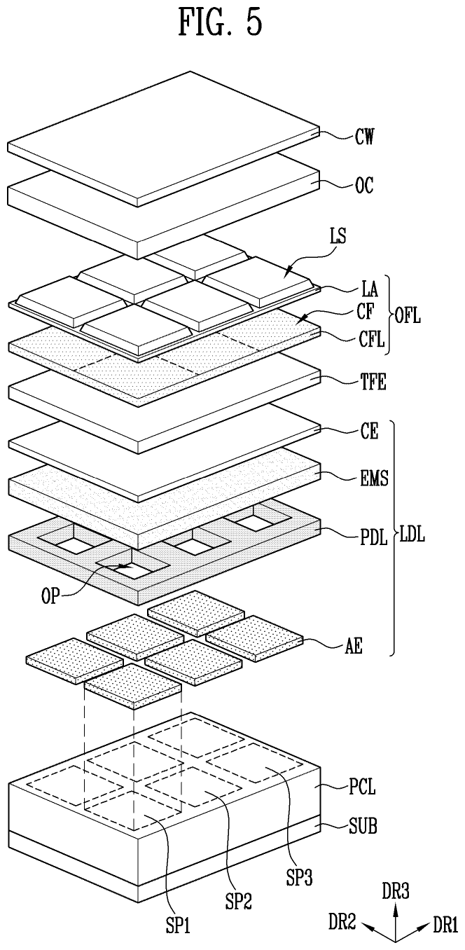

FIG. 5 illustrates an exploded perspective view of a portion of the display panel of FIG. 1.

The display panel DP may include a substrate SUB, a pixel circuit layer PCL, a light emitting element layer LDL, an encapsulation layer TFE, an optical functional layer OFL, an overcoat layer OC, and a cover window CW.

According to some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon on Insulator (SOI) layer, or a semiconductor on insulator (SeOI) layer. According to some embodiments, the substrate SUB may include a glass substrate. According to some embodiments, the substrate SUB may include a polyimide (PI) substrate.

The pixel circuit layer PCL is located on the substrate SUB. The substrate SUB and/or the pixel circuit layer PCL may include insulating layers and conductive patterns located between the insulating layers. The conductive patterns of the pixel circuit layer PCL may function as at least some of circuit elements, wires, and the like. The conductive patterns may include copper, but embodiments are not limited thereto.

The circuit elements may include the sub-pixel circuit SPC (see FIG. 3) for each of first to third sub-pixels SP1, SP2, and SP3. The sub-pixel circuit SPC may include transistors and at least one capacitor. Each transistor may include a semiconductor portion including a source region, a drain region, and a channel region, and a gate electrode overlapping the semiconductor portion. According to some embodiments, when the substrate SUB is provided as a silicon substrate, the semiconductor portion may be included in the substrate SUB, and the gate electrode may be included in the pixel circuit layer PCL as the conductive pattern of the pixel circuit layer PCL. According to some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer therebetween.

The wires of the pixel circuit layer PCL may include signal lines connected to each of the sub-pixel, for example, a gate line, a light emitting control line, and a data line. The wires may further include the wire connected to the first power voltage node VDDN of FIG. 3. In addition, the wires may further include the wire connected to the second power voltage node VSSN of FIG. 3.

The light emitting element layer LDL may include anode electrodes AE, a pixel defining film PDL, a light emitting structure EMS, and a cathode electrode CE.

The anode electrodes AE may be located on the pixel circuit layer PCL. The anode electrodes AE may contact circuit elements of the pixel circuit layer PCL. The anode electrodes AE may include a transparent conductive material. In this case, reflective electrodes may be located below the anode electrodes AE. Meanwhile, the anode electrodes AE may include an opaque conductive material capable of reflecting light.

The pixel defining film PDL is located on the anode electrodes AE. The pixel defining film PDL may include an opening OP exposing a portion of each of the anode electrodes AE. The opening OP of the pixel defining film PDL may be understood as light emitting areas corresponding to the first to third sub-pixels SP1 to SP3, respectively.

According to some embodiments, the pixel defining film PDL may include an inorganic material. In this case, the pixel defining film PDL may include a plurality of stacked inorganic layers. For example, the pixel defining film PDL may include a silicon oxide (SiOx) and a silicon nitride (SiNx). According to some embodiments, the pixel defining film PDL may include an organic material. However, the material of the pixel defining film PDL is not limited thereto.

The light emitting structure EMS may be located on the anode electrodes AE exposed by the opening OP of the pixel defining film PDL. The light emitting structure EMS may include a light emitting layer configured to generate light, an electron transport layer configured to transport electrons, and a hole transport layer configured to transport holes.

According to some embodiments, the light emitting structure EMS may fill the opening OP of the pixel defining film PDL, and may be arranged entirely on an upper portion of the pixel defining film PDL. In other words, the light emitting structure EMS may extend across the first to third sub-pixels SP1 to SP3. In this case, at least some of the layers in the light emitting structure EMS may be disconnected, bent, or removed at boundaries between the sub-pixels. However, embodiments are not limited thereto. For example, portions of the light emitting structure EMS corresponding to the sub-pixels may be separated from each other, and each of them may be located within the opening OP of the pixel defining film PDL.

The cathode electrode CE may be located on the light emitting structure EMS. The cathode electrode CE may extend across sub-pixels. As such, the cathode electrode CE may be provided as a common electrode for the sub-pixels.

The cathode electrode CE may be a thin metal layer with a thickness sufficient to transmit light emitted from the light emitting structure EMS. The cathode electrode CE may be made of a metallic material or a transparent conductive material to have a relatively thin thickness. According to some embodiments, the cathode electrode CE may include at least one of various transparent conductive materials including an indium tin oxide, an indium zinc oxide, an indium tin zinc oxide, an aluminum zinc oxide, a gallium zinc oxide, a zinc tin oxide, or a gallium tin oxide. According to some embodiments, the cathode electrode CE may include at least one of silver (Ag), magnesium (Mg), and/or a mixture thereof. However, the material of the cathode electrode CE is not limited thereto.

One of the anode electrodes AE, the portion of the light emitting structure EMS overlapping it, and the portion of the cathode electrode CE overlapping it may be understood to configure one light emitting element LD (see FIG. 3). In other words, each of the light emitting elements of the sub-pixels may include one anode electrode, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE are transported into the light emitting layer of the light emitting structure EMS to form excitons, and when the excitons transition from the excited state to the ground state, light may be generated. The luminance of light may be determined depending on the amount of current flowing through the light emitting layer. Depending on the configuration of the light emitting layer, the wavelength range of the generated light may be determined.

The encapsulation layer TFE is located on the cathode electrode CE. The encapsulation layer TFE may cover the light emitting element layer LDL and/or the pixel circuit layer PCL. The encapsulation layer TFE may be configured to prevent or reduce instances of contaminants such as oxygen and/or moisture penetrating into the light emitting element layer LDL. According to some embodiments, the encapsulation layer TFE may include a structure in which one or more inorganic films and one or more organic films are alternately stacked. For example, the inorganic film may include a silicon nitride, a silicon oxide, or a silicon oxynitride (SiOxNy). For example, the organic film may include an organic insulating material such as an acrylic resin, an epoxy resin, a phenol resin, a polyamide resin, a polyimide resin, an unsaturated polyesters resin, a polyphenylenethers resin, a polyphenylenesulfides resin, or a benzocyclobutene. However, the materials of the organic film and the inorganic film of the encapsulation layer TFE are not limited thereto.

The encapsulation layer TFE may further include a thin film containing an aluminum oxide (AlOx) in order to relatively improve the encapsulation efficiency of the encapsulation layer TFE. The thin film containing an aluminum oxide may be located on the upper surface of the encapsulation layer TFE facing the optical functional layer OFL and/or the lower surface of the encapsulation layer TFE facing the light emitting element layer LDL.

The thin film containing the aluminum oxide may be formed through atomic layer deposition (ALD). However, embodiments according to the present disclosure are not limited thereto. The encapsulation layer TFE may further include a thin film made of at least one of various materials suitable for relatively improving the encapsulation efficiency.

The optical functional layer OFL is located on the encapsulation layer TFE. The optical function layer OFL may include a color filter layer CFL and a lens array LA.

The color filter layer CFL is located between the encapsulation layer TFE and the lens array LA. The color filter layer CFL is configured to selectively output light in a wavelength range or color corresponding to each sub-pixel by filtering light emitted from the light emitting structure EMS. The color filter layer CFL includes color filters CF corresponding to the sub-pixels, and each of the color filters CF may pass light in a wavelength range corresponding to the sub-pixel. For example, a color filter corresponding to the first sub-pixel SP1 may pass red light, a color filter corresponding to the second sub-pixel SP2 may pass green light, and a color filter corresponding to the third sub-pixel SP3 may pass blue light. At least some of the color filters CF may be omitted according to light emitted from the light emitting structure EMS of each sub-pixel.

The lens array LA is located on the color filter layer CFL. The lens array LA may include lenses LS respectively corresponding to the sub-pixels. Each of the lenses LS may relatively improve light output efficiency by outputting light emitted from the light emitting structure EMS in an intended path. The lens array LA may have a relatively high refractive index. For example, the lens array LA may have a higher refractive index than the overcoat layer OC. According to some embodiments, the lenses LS may include an organic material. According to some embodiments, the lenses LS may include an acrylic material. However, the material of the lenses LS is not limited thereto.

According to some embodiments, compared to the opening OP of the pixel defining film PDL, at least some of the color filters CF of the color filter layer CF and at least some of the lenses LS of the lens array LA may be shifted in a direction parallel to a plane defined by the first and second directions DR1 and DR2. For example, in the center area of the display area DA, the center of the color filter and the center of the lens may be aligned or overlapped with the center of the opening OP of the corresponding pixel defining film PDL when viewed in the third direction DR3 (e.g., in a plan view). For example, in the central area of the display area DA, the opening OP of the pixel defining film PDL may completely overlap the corresponding color filter of the color filter layer CF and the corresponding lens of the lens array LA. In an area of the display area DA adjacent to the non-display area NDA, the center of the color filter and the center of the lens may be shifted in a planar direction from the center of the opening OP of the corresponding pixel defining film PDL when viewed in the third direction DR3. For example, in an area of the display area DA adjacent to the non-display area NDA, the opening OP of the pixel defining film PDL may partially overlap the corresponding color filter of the color filter layer CFL and the corresponding lens of the lens array LA. Accordingly, in the center of the display area DA, light emitted from the light emitting structure EMS may be efficiently outputted in the normal direction of the display surface. Light emitted from the light emitting structure EMS at the outside of the display area DA may be efficiently outputted in a direction inclined by an angle (e.g., a set or predetermined angle) with respect to the normal direction of the display surface.

The overcoat layer OC may be located on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign substances such as dust and moisture. For example, the overcoat layer OC may include at least one of an inorganic insulating film or an organic insulating film. For example, the overcoat layer OC may include an epoxy resin, but embodiments according to the present disclosure are not limited thereto. The overcoat layer OC may have a lower refractive index than the lens array LA.

The cover window CW may be located on the overcoat layer OC. The cover window CW is configured to protect lower layers thereof. The cover window CW may have a higher refractive index than the overcoat layer OC. The cover window CW may include glass, but embodiments according to the present disclosure are not limited thereto. For example, the cover window CW may be an encapsulation glass configured to protect constituent elements located thereunder. According to some embodiments, the cover window CW may be omitted.

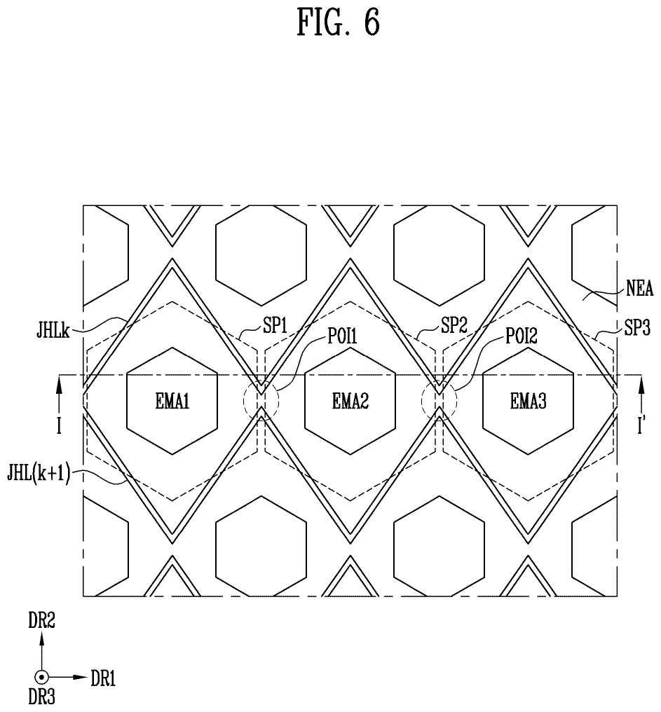

FIG. 6 illustrates a top plan view of a relationship between sub-pixels and metal lines.

Referring to FIG. 6, the first to third sub-pixels SP1, SP2, and SP3 arranged in first direction DR1 are illustrated as an example. The first to third sub-pixels SP1, SP2, and SP3 may be included in one pixel. In another example, the first to third sub-pixels SP1, SP2, and SP3 may be included in at least two different pixels. For example, the first sub-pixel SP1 and the second sub-pixel SP2 may be included in the first pixel, and the third sub-pixel SP3 may be included in the second pixel. The first sub-pixel SP1 may include a first light emitting area EMA1 and a non-light emitting area NEA around the first light emitting area EMA1. The second sub-pixel SP2 may include a second light emitting area EMA2 and a non-light emitting area NEA around the second light emitting area EMA2. The third sub-pixel SP3 may include a third light emitting area EMA3 and a non-light emitting area NEA around the third light emitting area EMA3.

The first light emitting area EMA1 may be an area in which light is emitted from a portion of the light emitting structure EMS (see FIG. 5) corresponding to the first sub-pixel SP1. The second light emitting area EMA2 may be an area in which light is emitted from a portion of the light emitting structure EMS corresponding to the second sub-pixel SP2. The third light emitting area EMA3 may be an area in which light is emitted from a portion of the light emitting structure EMS corresponding to the third sub-pixel SP3. As described with reference to FIG. 5, each light-emitting area may be understood as the opening OP of the pixel defining film PDL corresponding to each of the first to third sub-pixels SP1 to SP3.

In FIG. 6, the light emitting areas EMA1, EMA2, and EMA3 are illustrated as hexagonal shapes, but the light emitting areas EMA1, EMA2, and EMA3 may be configured in other polygonal shapes including a quadrangular shape. Meanwhile, the light emitting areas EMA1, EMA2, and EMA3 may be configured in a circular or oval shape. In addition, the shapes and areas of different light emitting areas EMA1, EMA2, and EMA3 may be the same or different.

The metal lines JHLk and JHL(k+1) extend in the first direction DR1, and may have a shape surrounding the corresponding light emitting areas EMA1, EMA2, and EMA3. For example, the metal lines JHLk and JHL(k+1) may extend in the first direction DR1, and may extend in a zigzag shape. In addition, the metal lines JHLk and JHL k+1) may be configured in various shapes, such as a polygonal shape, a circular shape, and an elliptical shape, corresponding to the various shapes of the light emitting areas EMA1, EMA2, and EMA3.

However, since the metal lines JHLk and JHL(k+1) are not connected to each other on the display area DA, areas POI1 and POI2 that are not covered by the metal lines JHLk and JHL(k+1) may exist between the adjacent light emitting areas EMA1, EMA2, and EMA3. However, two or more metal lines JHLk and JHL(k+1) may be located adjacent to each other with a minimum gap in the areas POI1 and POI2. According to some embodiments, an organic material existing in the areas POI1 and POI2 that do not overlap the metal lines JHLk and JHL(k+1) may be sublimated due to heat generated from two adjacent metal lines JHLk and JHL(k+1), and thus a leakage current through the organic material may be prevented or reduced.

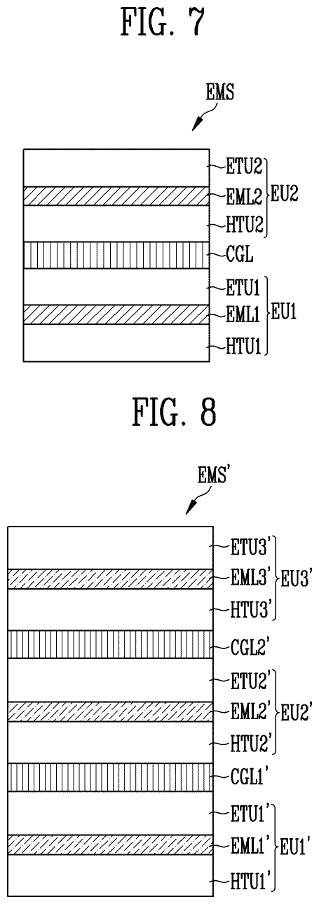

FIG. 7 illustrates a cross-sectional view of a light emitting structure according to some embodiments.

Referring to FIG. 7, the light emitting structure EMS may have a tandem structure in which first and second light emitting portions EU1 and EU2 are stacked.

Each of the first and second light emitting portions EU1 and EU2 may include a light emitting layer that generates light according to a current applied thereto. The first light emitting portion EU1 may include a first light emitting layer EML1, a first electron transport portion ETU1, and a first hole transport portion HTU1. The first light emitting layer EML1 may be located between the first electron transport portion ETU1 and the first hole transport portion HTU1. The second light emitting portion EU2 may include a second light emitting layer EML2, a second electron transport portion ETU2, and a second hole transport portion HTU2. The second light emitting layer EML2 may be located between the second electron transport portion ETU2 and the second hole transport portion HTU2.

Each of the first and second hole transport portions HTU1 and HTU2 may include at least one of a hole injection layer or a hole transport layer, and may further include a hole buffer layer, an electron blocking layer, or the like as needed. The first and second hole transport portions HTU1 and HTU2 may have the same configuration or different configurations.

Each of the first and second electron transport portions ETU1 and ETU2 may include at least one of an electron injection layer or an electron transport layer, and may further include an electron buffer layer and a hole blocking layer as needed. The first and second electron transport portions ETU1 and ETU2 may have the same configuration or different configurations.

A connection layer, which may be provided in the form of a charge generation layer CGL, may be located between the first light emitting portion EU1 and the second light emitting portion EU2 to connect them to each other. According to some embodiments, the charge generation layer CGL may have a stacked structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide-based metal, or a combination thereof. However, embodiments according to the present disclosure are not limited thereto.

According to some embodiments, the first light emitting layer EML1 and the second light emitting layer EML2 may generate light of different colors. The light emitted from each of the first light emitting layer EML1 and the second light emitting layer EML2 may be mixed to be recognized as white light. For example, the first light emitting layer EML1 may generate blue-colored light, and the second light emitting layer EML2 may generate yellow-colored light. According to some embodiments, the second light-emitting layer EML2 may include a structure in which a first sub-light-emitting layer configured to generate red-colored light and a second sub-light-emitting layer configured to generate green-colored light are stacked. The red-colored light and the green-colored light may be mixed to provide yellow-colored light. In this case, an intermediate layer configured to perform a function of transporting holes and/or preventing or reducing transport of electrons may be further located between the first and second sub-light emitting layers.

According to some embodiments, the first light emitting layer EML1 and the second light emitting layer EML2 may generate light of the same color.

According to some embodiments, the light emitting structure EMS may be formed through a vacuum deposition method, an inkjet printing method, or the like, but embodiments are not limited thereto.

FIG. 8 illustrates a cross-sectional view of a light emitting structure according to some embodiments.

Referring to FIG. 8, a light emitting structure EMS′ may have a tandem structure in which first to third light emitting portions EU1′ to EU3′ are stacked.

Each of the first to third light emitting portions EU1′ to EU3′ may include a light emitting layer that generates light according to a current applied thereto. The first light emitting portion EU1′ may include a first light emitting layer EML1′, a first electron transport portion ETU1′, and a first hole transport portion HTU1′. The first light emitting layer EML1′ may be located between the first electron transport portion ETU1′ and the first hole transport portion HTU1′. The second light emitting portion EU2′ may include a second light emitting layer EML2′, a second electron transport portion ETU2′, and a second hole transport portion HTU2′. The second light emitting layer EML2′ may be located between the second electron transport portion ETU2′ and the second hole transport portion HTU2′. The third light emitting portion EU3′ may include a third light emitting layer EML3′, a third electron transport portion ETU3′, and a third hole transport portion HTU3′. The third light emitting layer EML3′ may be located between the third electron transport portion ETU3′ and the third hole transport portion HTU3′.

Each of the first to third hole transport portions HTU1′ to HTU3′ may include at least one of a hole injection layer or a hole transport layer, and may further include a hole buffer layer, an electron blocking layer, or the like as needed. The first to third hole transport portions HTU1′ to HTU3′ may have the same configuration or different configurations.

Each of the first to third electron transport portions ETU1′ to ETU3′ may include at least one of an electron injection layer or an electron transport layer, and may further include an electron buffer layer and a hole blocking layer as needed. The first to third electron transport portions ETU1′ to ETU3′ may have the same configuration or different configurations.

A first charge generation layer CGL1′ is located between the first light emitting portion EU1′ and the second light emitting portion EU2′. A second charge generation layer CGL2′ is located between the second light emitting portion EU2′ and the third light emitting portion EU3′.

According to some embodiments, the first to third light emitting layers EML1′ to EML3′ may generate light of different colors. Light emitted from each of the first to third light emitting layers EML1′ to EML3′ may be mixed to be viewed as white light. For example, the first light emitting layer EML1′ may generate light of a blue color, the second light emitting layer EML2′ may generate light of a green color, and the third light emitting layer EML3′ may generate light of a red color.

According to some embodiments, two or more of the first to third light emitting layers EML1′ to EML3′ may generate light of the same color.

Unlike illustrated in FIG. 7 and FIG. 8, each light emitting structure EMS of each sub-pixel may include one light emitting portion. In this case, light emitting portions included in different sub-pixels SP1, SP2, and SP3 adjacent to each other may be configured to emit light of different colors. For example, the light emitting portion of the first sub-pixel SP1 may emit red-colored light, the light emitting portion of the second sub-pixel SP2 may emit green-colored light, and the light emitting portion of the third sub-pixel SP3 may emit blue-colored light. In this case, the light emitting portions of the first to third sub-pixels SP1 to SP3 are separated from each other, and each of them may be located in the opening OP of the pixel defining film PDL. In this case, at least some of the color filters CF1 to CF3 may be omitted.

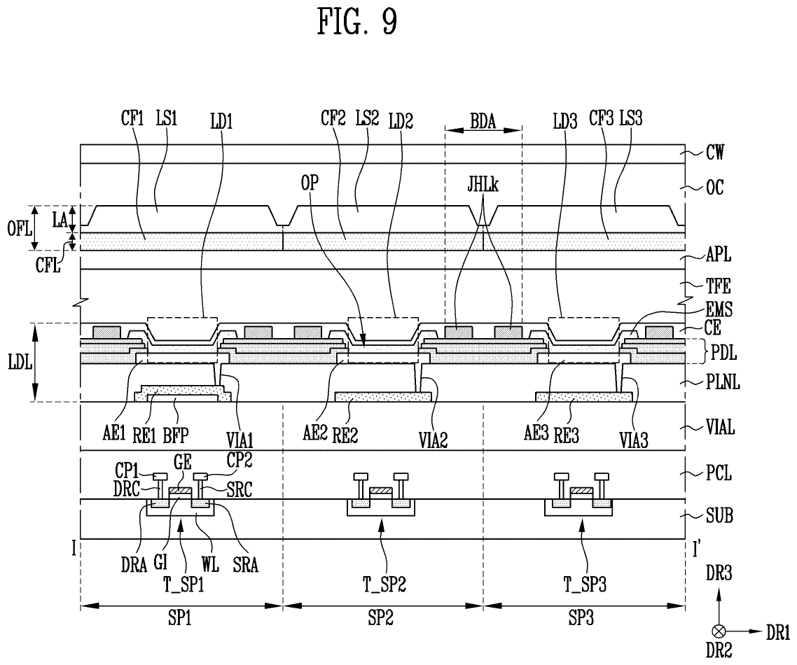

FIG. 9 illustrates a cross-sectional view taken along the line I-I′ of FIG. 6.

Referring to FIG. 9, the substrate SUB and the pixel circuit layer PCL located on the substrate SUB are provided.

The substrate SUB may include a silicon wafer substrate formed using a semiconductor process. For example, the substrate SUB may include silicon, germanium, and/or silicon-germanium.

The pixel circuit layer PCL is located on the substrate SUB. The substrate SUB and the pixel circuit layer PCL may include circuit elements for each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see FIG. 4) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 9, for clear and concise description, one of the transistors of each sub-pixel is shown and the remaining circuit elements are omitted.

The transistor T_SP1 of the first sub-pixel SP1 may include a source area SRA, a drain area DRA, and a gate electrode GE.

The source area SRA and the drain area DRA may be located within the substrate SUB. A well WL formed through an ion injection process is located in the substrate SUB, and the source area SRA and the drain area DRA may be arranged to be spaced apart from each other within the well WL. The area between the source area SRA and the drain area DRA within the well WL may be defined as a channel area.

The gate electrode GE overlaps the channel area between the source area SRA and the drain area DRA, and may be located on the pixel circuit layer PCL. The gate electrode GE may be separated from the well WL or the channel area by an insulating material such as a gate insulating layer GI. The gate electrode GE may include a conductive material.

A plurality of layers included in the pixel circuit layer PCL include insulating layers and conductive patterns located between the insulating layers, and the conductive patterns may include first and second conductive patterns CP1 and CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are connected to other circuit elements and/or wires, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1. As described above, the substrate SUB and the pixel circuit layer PCL may include circuit elements for each of the first to third sub-pixels SP1 to SP3.

A via layer VIAL is located on the pixel circuit layer PCL. The via layer VIAL covers the pixel circuit layer PCL, and may have an overall lat surface. The via layer VIAL is configured to flatten steps on the pixel circuit layer PCL. The via layer VIAL may include at least one of a silicon oxide (SiOx), a silicon nitride (SiNx), or a silicon carbon nitride (SiCN), but embodiments are not limited thereto.

The light emitting element layer LDL is located on the via layer VIAL. The light emitting element layer LDL may include first to third reflective electrodes RE1 to RE3, a planarization layer PLNL, first to third anode electrodes AE1 to AE3, a pixel defining film PDL, a light emitting structure EMS, and a cathode electrode CE.

The first to third reflective electrodes RE1 to RE3 are located in the first to third sub-pixels SP1 to SP3 on the via layer VIAL, respectively. Each of the first to third reflective electrodes RE1 to RE3 may contact a circuit element located on the pixel circuit layer PCL through a via penetrating the via layer VIAL.

The first to third reflective electrodes RE1 to RE3 may function as full mirrors that reflect light emitted from the light emitting structure EMS toward the display surface (or the cover window CW). The first to third reflective electrodes RE1 to RE3 may include metallic materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected therefrom, but embodiments are not limited thereto.

According to some embodiments, a connection electrode may be located below each of the first to third reflective electrodes RE1 to RE3. The connection electrode may relatively improve the electrical connection characteristics between the corresponding reflective electrode and the circuit element of the pixel circuit layer PCL. The connection electrode may have a multi-layered structure. The multi-layered structure may include titanium (Ti), a titanium nitride (TiN), a tantalum nitride (TaN), and the like, but embodiments are not limited thereto. According to some embodiments, a corresponding reflective electrode may be located between the multiple layers of the connecting electrode.

A buffer pattern BFP may be located below at least one of the first to third reflective electrodes RE1 to RE3. The buffer pattern BFP may include an inorganic material such as a silicon carbon nitride, but embodiments are not limited thereto. By arranging or forming the buffer pattern BFP, the height of the corresponding reflective electrode in the third direction DR3 may be adjusted. For example, the buffer pattern BFP may be located between the first reflective electrode RE1 and the via layer VIAL to adjust the height of the first reflective electrode RE1.

The first to third reflective electrodes RE1 to RE3 may function as full mirrors, and the cathode electrode CE may function as a half mirror. Light emitted from the light emitting layer of the light emitting structure EMS may be amplified at least partially by reciprocating between the reflective electrode and the cathode electrode CE, and the amplified light may be outputted through the cathode electrode CE. As such, the distance between each reflective electrode and the cathode electrode CE may be understood as the resonance distance for the light emitted from the light emitting layer of the corresponding light emitting structure EMS.

The first sub-pixel SP1 may have a shorter resonance distance than other sub-pixels due to the buffer pattern BFP. The resonance distance adjusted in this way may allow light in a specific wavelength range (for example, red color) to be effectively and efficiently amplified. Accordingly, the first sub-pixel SP1 may effectively and efficiently output light in the corresponding wavelength range.

In FIG. 9, the buffer pattern BFP is shown to be provided in the first sub-pixel SP1 and not in the second and third sub-pixels SP2 and SP3, but the embodiments are not limited thereto. The buffer pattern may be also provided in at least one of the second or third sub-pixels SP2 or SP3, so that the resonance distance of at least one of the second or third sub-pixels SP2 or SP3 may be adjusted. For example, the first to third sub-pixels SP1 to SP3 may correspond to red, green, and blue, respectively, the distance between the first reflective electrode RE1 and the cathode electrode CE may be shorter than the distance between the second reflective electrode RE2 and the cathode electrode CE, and the distance between the second reflective electrode RE2 and the cathode electrode CE may be shorter than the distance between the third reflective electrode RE3 and the cathode electrode CE.

To planarize the steps between the first to third reflective electrodes RE1 to RE3, the planarization layer PLNL may be located on the via layer VIAL and the first to third reflective electrodes RE1 to RE3. The planarization layer PLNL may entirely cover the first to third reflective electrodes RE1 to RE3 and the via layer VIAL, and may have a flat surface. According to some embodiments, the planarization layer PLNL may be omitted.

The first to third anode electrodes AE1 to AE3 respectively overlapping the first to third reflective electrodes RE1 to RE3 are located on the planarization layer PLNL. The first to third anode electrodes AE1 to AE3 may have shapes similar to the first to third light emitting areas EMA1 to EMA3 of FIG. 7 when viewed in the third direction DR3. The first to third anode electrodes AE1 to AE3 are respectively connected to the first to third reflective electrodes RE1 to RE3. The first anode electrode AE1 may be connected to the first reflective electrode RE1 through the first via VIA1 penetrating the planarization layer PLNL. The second anode electrode AE2 may be connected to the second reflective electrode RE2 through the second via VIA2 penetrating the planarization layer PLNL. The third anode electrode AE3 may be connected to the third reflective electrode RE3 through the third via VIA3 penetrating the planarization layer PLNL.

According to some embodiments, the first to third anode electrodes AE1 to AE3 may include at least one of a transparent conductive materials such as an indium tin oxide (ITO), an indium zinc oxide (IZO), a zinc oxide (ZnOx), an indium gallium zinc oxide (IGZO), or an indium tin zinc oxide (ITZO). However, the materials of the first to third anode electrodes AE1 to AE3 are not limited thereto. For example, the first to third anode electrodes AE1 to AE3 may include a titanium nitride.

According to some embodiments, insulating layers for adjusting a height of one or more of the first to third anode electrodes AE1 to AE3 may be further provided. The insulating layers may be located between at least one of the first to third anode electrodes AE1 to AE3 and the corresponding reflective electrode. In this case, the planarization layer PLNL and/or the buffer pattern BFP may be omitted. For example, the first to third sub-pixels SP1 to SP3 may respectively correspond to red, green, and blue, the distance between the first anode electrode AE1 and the cathode electrode CE may be shorter than the distance between the second anode electrode AE2 and the cathode electrode CE, and the distance between the second anode electrode AE2 and the cathode electrode CE may be shorter than the distance between the third anode electrode AE3 and the cathode electrode CE. The pixel defining film PDL is located on some of the first to third anode electrodes AE1 to AE3 and the planarization layer PLNL. The pixel defining film PDL may include an opening OP exposing a portion of each of the first to third anode electrodes AE1 to AE3. The opening OP of the pixel defining film PDL may define the light emitting area for each of the first to third sub-pixels SP1 to SP3. As such, the pixel defining film PDL may be located in the non-light emitting area NEA of FIG. 6 to define the first to third light emitting areas EMA1 to EMA3 of FIG. 6.

According to some embodiments, the pixel defining film PDL may include a plurality of inorganic insulating layers. Each of the plurality of inorganic insulating layers may include at least one of a silicon oxide (SiOx) or a silicon nitride (SiNx). For example, the pixel defining film PDL may include first to third inorganic insulating layers sequentially stacked, and each of the first to third inorganic insulating layers may include a silicon nitride, a silicon oxide, and a silicon oxynitride. However, embodiments are not limited thereto. The first to third inorganic insulating layers may have a step-shaped cross-section in an area adjacent to the opening OP.

The metal line JHLk may be provided in the boundary area BDA between neighboring sub-pixels. Each of the metal lines (JHL1 to JHLo) including the metal line JHLk may be located on the pixel defining film PDL (see FIG. 7).

Each of the metal lines JHL1 to JHLo including the metal line JHLk may contact the cathode electrode CE of the light emitting elements of the sub-pixels SP in the display area DA. For example, the metal lines JHL1 to JHLo may sublimate a portion of the light emitting structure EMS located nearby by dissipating heat by Joule heating after the light emitting structure EMS is stacked. In the case of the light emitting structure EMS of FIG. 7, the light emitting structure EMS may not remain on the metal line JHLk because a Joule heating process is performed after the first light emitting portion EU1, the charge generation layer CGL, and the second light emitting portion EU2 are all stacked. In the case of the light emitting structure EMS of FIG. 8, the light emitting structure EMS′ may not remain on the metal line JHLk because a Joule heating process is performed after the first light emitting portion EU1′, the first charge generation layer CGL1′, the second light emitting portion EU2′, the second charge generation layer CGL2′, and the third light emitting portion EU3′ are all stacked. Accordingly, a leakage current through portions of the light emitting structure EMS cut off by the metal lines JHL1 to JHLo may be prevented or reduced. The metal lines JHL1 to JHLo may be exposed to the outside of the light emitting structure EMS, and may contact the cathode electrode CE that is subsequently deposited.

The light emitting structure EMS may be located on the anode electrodes AE exposed by the opening OP of the pixel defining film PDL. According to some embodiments, the light emitting structure EMS may be formed through processes such as vacuum deposition or inkjet printing. The light emitting structure EMS may fill the opening OP of the pixel defining film PDL, and may be arranged entirely across the first to third sub-pixels SP1 to SP3. As previously described, the light emitting structure EMS may be at least partially cut off in the boundary area BDA by the metal line JHLk. Accordingly, when the display panel DP operates, the current leaking from each of the first to third sub-pixels SP1 to SP3 to the neighboring sub-pixel through the layers included in the light-emitting structure EMS may decrease. Accordingly, the first to third light emitting elements LD1 to LD3 may operate with relatively high reliability.

The cathode electrode CE may be located on the light emitting structure EMS. The cathode electrode CE may be provided commonly for the first to third sub-pixels SP1 to SP3. The cathode electrode CE may function as a half mirror that partially transmits and partially reflects light emitted from the light emitting structure EMS.

The first anode electrode AE1, the portion of the light emitting structure EMS overlapping the first anode electrode AE1, and the portion of the cathode electrode CE overlapping the first anode electrode AE1 may configure the first light emitting element LD1. The second anode electrode AE2, the portion of the light emitting structure EMS overlapping the second anode electrode AE2, and the portion of the cathode electrode CE overlapping the second anode electrode AE2 may configure the second light emitting element LD2. The third anode electrode AE3, the portion of the light emitting structure EMS overlapping the third anode electrode AE3, and the portion of the cathode electrode CE overlapping the third anode electrode AE3 may configure the third light emitting element LD3.

The encapsulation layer TFE is located on the cathode electrode CE. The encapsulation layer TFE may prevent or reduce instances of contaminants such as oxygen and/or moisture penetrating into the light emitting element layer LDL.

The optical functional layer OFL is located on the encapsulation layer TFE. According to some embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may pass light in different wavelength ranges. For example, the first to third color filters CF1 to CF3 may pass red, green, and blue colored light, respectively.

According to some embodiments, the first to third color filters CF1 to CF3 may partially overlap in the boundary area BDA. According to some embodiments, the first to third color filters CF1 to CF3 may be spaced apart from each other, and a black matrix may be provided between the first to third color filters CF1 to CF3.

The lens array LA is located on the color filter layer CFL. The lens array LA may include first to third lenses LS1 to LS3 respectively corresponding to the first to third sub-pixels SP1 to SP3. The first to third lenses LS1 to LS3 may relatively improve light output efficiency by outputting the light emitted from the first to third light emitting elements LD1 to LD3, respectively, along an intended path.

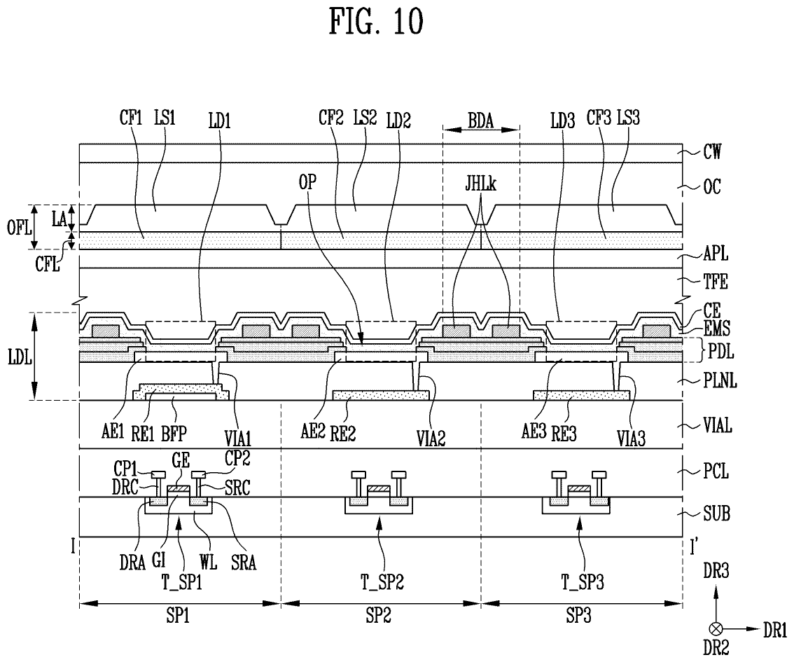

FIG. 10 illustrates a cross-sectional view according to some embodiments of FIG. 9.

The light emitting structure EMS of FIG. 10 is different from the light emitting structure EMS of FIG. 9 in that a portion of the light emitting structure EMS remains on the metal line JHLk. That is, each of the metal lines JHL1 to JHLo including the metal line JHLk may not contact the cathode electrode CE of the light emitting elements of the sub-pixels SP in the display area DA.

For example, after the first light emitting portion EU1 and the charge generation layer CGL are stacked on the metal line JHLk, heat by Joule heating is emitted from the metal line JHLk, thereby sublimating a portion of the first light emitting portion EU1 and the charge generation layer CGL located nearby. Thereafter, stacking of the second light emitting portion EU2 may proceed (see FIG. 7). In this case, the metal line JHLk may contact the remaining second light emitting portion EU2.

For another example, after the first light emitting portion EU1′, the first charge generation layer CGL1′, the second light emitting portion EU2′, and the second charge generation layer CGL2′ are stacked on the metal line JHLk, portions of the first light emitting portion EU1′, the first charge generation layer CGL1′, the second light emitting portion EU2′, and the second charge generation layer CGL2′ may be sublimated by dissipating heat by Joule heating in the metal line JHLk. Thereafter, stacking of the third light emitting portion EU3′ may proceed (see FIG. 8). In this case, the metal line JHLk may contact the remaining third light emitting portion EU3′.

Since the highly conductive charge generation layer CGL, first charge generation layer CGL1′, or second charge generation layer CGL2′ may be sublimated, a leakage current may be prevented or reduced even if a portion of the light emitting structure EMS remains.

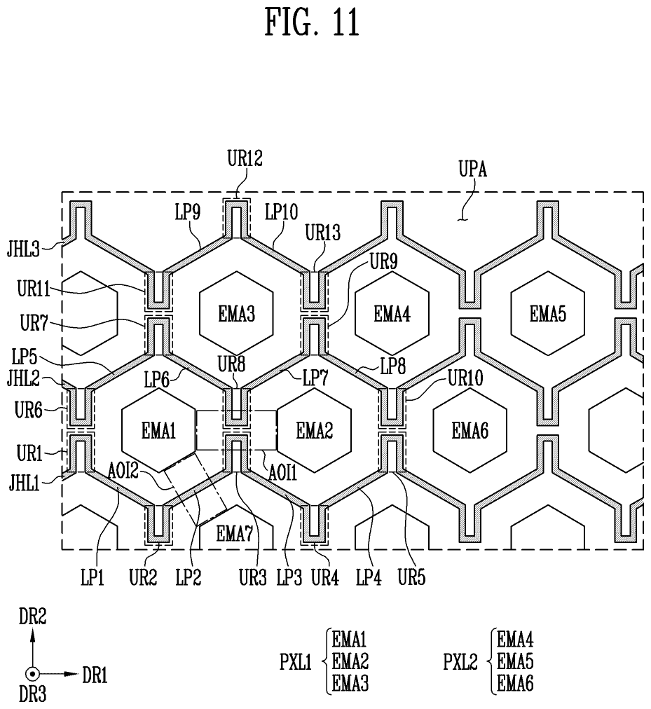

FIG. 11 is a drawing for explaining metal lines according to some embodiments.

A first pixel PXL1 may include the first sub-pixel and the second sub-pixel arranged in the first direction DR1. In addition, the first pixel PXL1 may include a third sub-pixel arranged in the second direction DR2 between the first sub-pixel and the second sub-pixel. The first sub-pixel may include the first light emitting area EMA1, the second sub-pixel may include the second light emitting area EMA2, and the third sub-pixel may include the third light emitting area EMA3. The first to third light emitting areas EMA1, EMA2, and EMA3 may be hexagonal. According to some embodiments, the first to third light emitting areas EMA1, EMA2, and EMA3 may be circular. The shapes of the first to third light emitting areas EMA1, EMA2, and EMA3 are not limited and may vary from product to product.

The second pixel PXL2 may include a fourth sub-pixel and a fifth sub-pixel arranged in the first direction DR1. In addition, the second pixel PXL2 may include a sixth sub-pixel arranged in a direction opposite to the second direction DR2 between the fourth sub-pixel and the fifth sub-pixel. The fourth sub-pixel may include a fourth light emitting area EMA4, the fifth sub-pixel may include a fifth light emitting area EMA5, and the sixth sub-pixel may include a sixth light emitting area EMA6. The fourth to sixth light emitting areas EMA4, EMA5, and EMA6 may be hexagonal. According to some embodiments, the fourth to sixth light emitting areas EMA4, EMA5, and EMA6 may be circular. The shapes of the fourth to sixth light emitting areas EMA4, EMA5, and EMA6 are not limited and may vary from product to product.

Hereinafter, the description will be based on the first pixel PXL1. The same description may be applied to the second pixel PXL2 and other pixels.

Respective metal lines (JHL1, JHL2, JHL3, . . . ) may include metal patterns (UR1 to UR13, . . . ) that extend in the first direction DR1 so as not to overlap the light emitting areas (EMA1 to EMA7 . . . ) of the sub-pixels and that protrude in a direction crossing the first direction DR1 between the light emitting areas (EMA1 to EMA7 . . . ). Each of the metal patterns (UR1 to UR13, . . . ) may have a shape in which two or more layers of wires are densely packed together. Each of the metal patterns (UR1 to UR13, . . . ) may have a ring shape.

The metal lines (JHL1, JHL2, JHL3, . . . ) may include first metal lines (JHL1, JHL3, . . . ) and second metal lines (JHL2, . . . ). The first metal lines (JHL1, JHL3, . . . ) and the second metal lines (JHL2, . . . ) may be alternately arranged in the second direction DR2. According to some embodiments, the first metal lines (JHL1, JHL3, . . . ) and the second metal lines (JHL2, . . . ) may have shapes that are symmetrical to each other with respect to the second direction DR2. For example, each of the metal patterns of the first metal lines (JHL1, JHL3, . . . ) may protrude to face the adjacent metal pattern of the adjacent second metal line.

Each of the metal lines (JHL1, JHL2, JHL3, . . . ) may include metal patterns (UR1 to UR13, . . . ) that protrude alternately in the second direction DR2 and in a direction opposite to the second direction DR2. For example, the first metal line JHL1 may sequentially include the first metal pattern UR1 protruding in the second direction DR2, the second metal pattern UR2 protruding in a direction opposite to the second direction DR2, the third metal pattern UR3 protruding in the second direction DR2, the fourth metal pattern UR4 protruding in a direction opposite to the second direction DR2, and the fifth metal pattern UR5 protruding in the second direction DR2, along the first direction DR1. The first light emitting area EMA1 may be arranged in the second direction DR2 from the second metal pattern UR2. The second light emitting area EMA2 may be arranged in the second direction DR2 from the fourth metal pattern UR4.

Each of the metal lines (JHL1, JHL2, JHL3, . . . ) may further include line patterns (LP1 to LP10, . . . ) that connect the metal patterns (UR1 to UR13, . . . ). For example, the first metal line JHL1 may include a first line pattern LP1 connecting the first metal pattern UR1 and the second metal pattern UR2, a second line pattern LP2 connecting the second metal pattern UR2 and the third metal pattern UR3, a third line pattern LP3 connecting the third metal pattern UR3 and the fourth metal pattern UR4, and a fourth line pattern LP4 connecting the fourth metal pattern UR4 with the fifth metal pattern UR5.

The line patterns (LP1 to LP10, . . . ) may have an inclined shape in a plan view to correspond to the outer periphery of the adjacent light emitting areas (EMA1 to EMA7, . . . ). For example, the first line pattern LP1 and the third line pattern LP3 may be parallel to each other. For example, the first line pattern LP1 and the third line pattern LP3 may extend in a direction between a direction opposite to the second direction DR2 and the first direction DR1. The second line pattern LP2 and the fourth line pattern LP4 may be parallel to each other. For example, the second line pattern LP2 and the fourth line pattern LP4 may extend in a direction between the second direction DR2 and the first direction DR1. Accordingly, the first line pattern LP1 and the second line pattern LP2 may not be parallel to each other.

The second metal line JHL2 may sequentially include the sixth metal pattern UR6 protruding in a direction opposite to the second direction DR2, the seventh metal pattern UR7 protruding in the second direction DR2, the eighth metal pattern UR8 protruding in a direction opposite to the second direction DR2, the ninth metal pattern UR9 protruding in the second direction DR2, and the tenth metal pattern UR10 protruding in a direction opposite to the second direction DR2, along the first direction DR1. The first light emitting area EMA1 may be arranged in a direction opposite to the second direction DR2 from the seventh metal pattern UR7. The second light emitting area EMA2 may be arranged in a direction opposite to the second direction DR2 from the ninth metal pattern UR9. The third light emitting area EMA3 may be arranged in the second direction DR2 from the eighth metal pattern UR8. The metal pattern protruding in the second direction DR2 may face an adjacent metal pattern protruding in a direction opposite to the second direction DR2. For example, the third metal pattern UR3 and the eighth metal pattern UR8 may face each other between the first light emitting area EMA1 and the second light emitting area EMA2.

The second metal line JHL2 may include a fifth line pattern LP5 connecting the sixth metal pattern UR6 and the seventh metal pattern UR7, a sixth line pattern LP6 connecting the seventh metal pattern UR7 and the eighth metal pattern UR8, a seventh line pattern LP7 connecting the eighth metal pattern UR8 and the ninth metal pattern UR9, and an eighth line pattern LP8 connecting the ninth metal pattern UR9 and the tenth metal pattern UR10.

The third metal line JHL3 may sequentially include, along the first direction DR1, the eleventh metal pattern UR11 protruding in a direction opposite to the second direction DR2, the twelfth metal pattern UR12 protruding in the second direction DR2, and the thirteenth metal pattern UR13 protruding in a direction opposite to the second direction DR2. The third light emitting area EMA3 may be arranged in a direction opposite to the second direction DR2 from the twelfth metal pattern UR12. The eleventh metal pattern UR11 and the seventh metal pattern UR7 may face each other in the second direction DR2. The thirteenth metal pattern UR13 and the ninth metal pattern UR9 may face each other in the second direction DR2.

The third metal line JHL3 may include a ninth line pattern LP9 connecting the eleventh metal pattern UR11 and the twelfth metal pattern UR12, and a tenth line pattern LP10 connecting the twelfth metal pattern UR12 and the thirteenth metal pattern UR13.

In the embodiments of FIG. 11, an upper area UPA in the non-display area NDA arranged in the second direction DR2 of the light emitting areas EMA3, EMA4, and EMA5 may not include a dummy metal line. This is because the third metal line JHL3 located in the display area DA may prevent or reduce a leakage current in the second direction DR2 of the light emitting areas EMA3, EMA4, and EMA5.

Lengths of the metal lines (JHL1, JHL2, JHL3, . . . ) may be the same. Accordingly, resistance values of the metal lines (JHL1, JHL2, JHL3, . . . ) may be the same, and heat due to the Joule heating process may be uniformly generated.

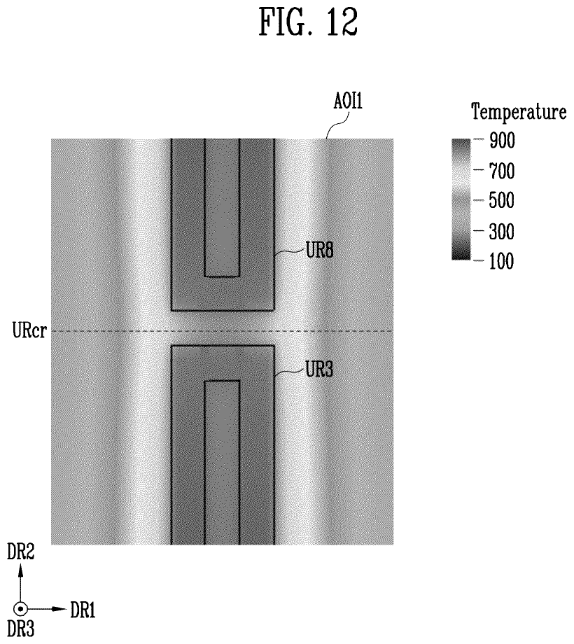

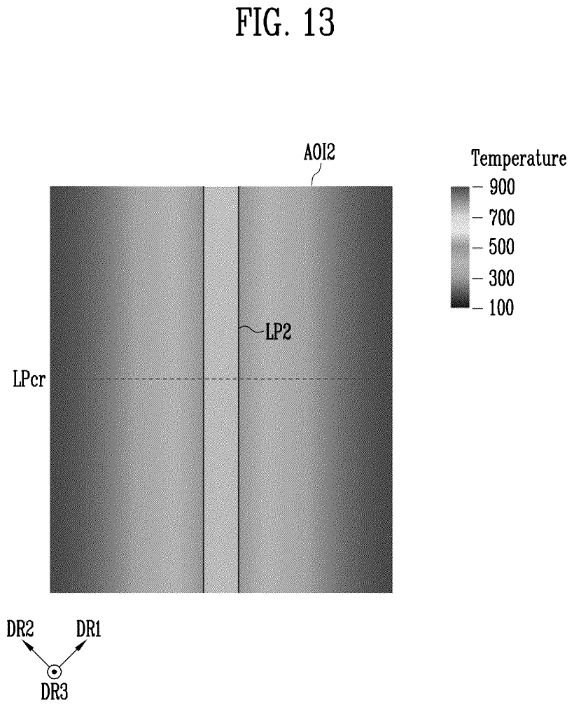

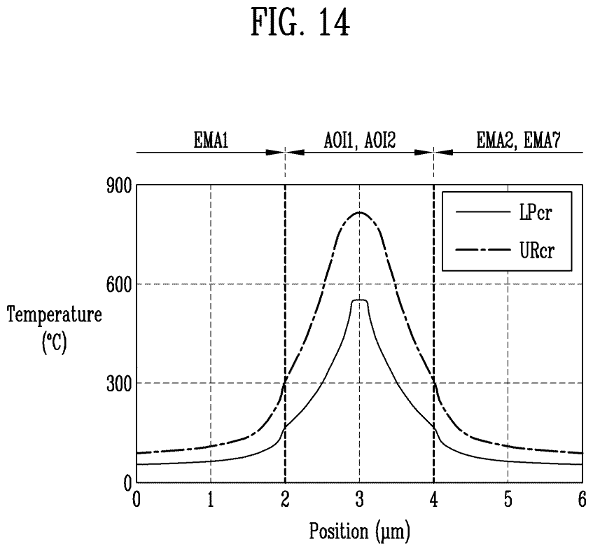

FIG. 12 is a drawing for explaining a temperature of a metal pattern of a metal line of FIG. 11. FIG. 13 is a drawing for explaining a temperature of a line pattern of a metal line of FIG. 11. FIG. 14 illustrates temperature graphs of areas of interest in FIG. 12 and FIG. 13.

FIG. 12 illustrates a heat distribution diagram for a first area of interest AOI1 of FIG. 11. The first area of interest AOI1 may include the third metal pattern UR3 and the eighth metal pattern UR8 facing each other between the first light emitting area EMA1 and the second light emitting area EMA2.

The first metal line JHL1 and the second metal line JHL2 are not connected to each other between the first light emitting area EMA1 and the second light emitting area EMA2. However, in order to prevent or reduce a leakage current between the first light emitting area EMA1 and the second light emitting area EMA2, organic material sublimation is also required for the portion not covered by the first metal line JHL1 and the second metal line JHL2 (see the description of FIG. 6). Accordingly, by arranging the metal patterns UR3 and UR8, which are densely packed with two or more layers of wires, between the first light emitting area EMA1 and the second light emitting area EMA2, the organic material between the metal patterns UR3 and UR8 may also be sublimated.

FIG. 13 illustrates a heat distribution diagram for a second area of interest AOI2 of FIG. 11. The second area of interest AOI2 may include the second line pattern LP2 extending between the first light emitting region EMA1 and the seventh light emitting region EMA7.

Referring to FIG. 14, it can be seen that the temperature of the virtual line URcr of the first area of interest AOI1 in which a plurality of wires are densely arranged is higher than the temperature of the virtual line LPcr of the second area of interest AOI2 in which a single wire is located. In this case, in the case of the first area of interest AOI1, there is a risk that the organic materials in the light emitting areas EMA1 and EMA2 may be sublimated.

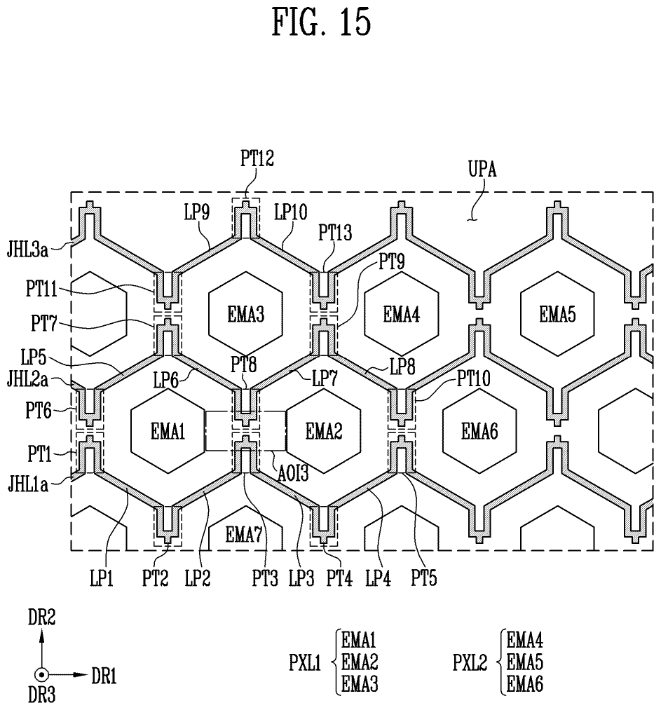

FIG. 15 is a drawing for explaining metal lines according to some embodiments. In describing FIG. 15, some descriptions of content overlapping with FIG. 11 may be omitted.

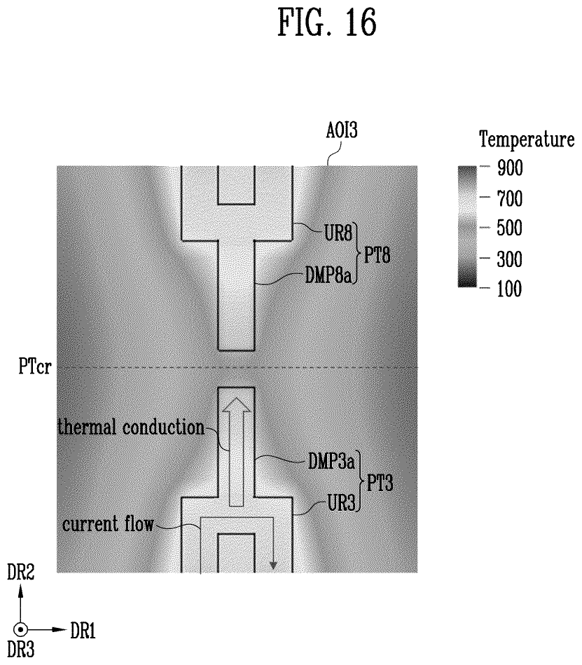

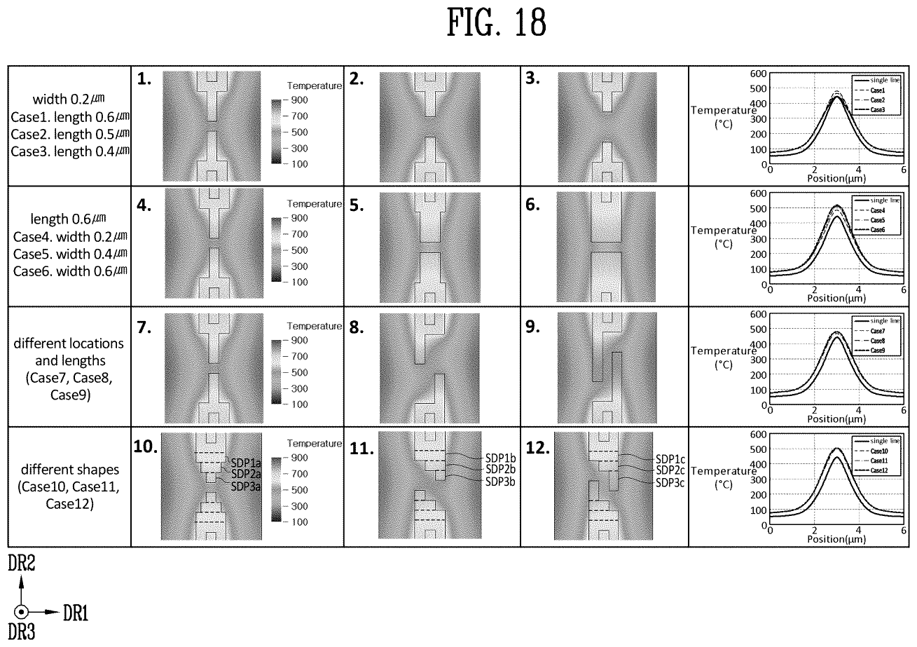

Respective metal lines (JHL1a, JHL2a, JHL3a, . . . ) may include protruding patterns (PT1 to PT13, . . . ) that extend in the first direction DR1 so as not to overlap the light emitting areas (EMA1 to EMA7 . . . ) of the sub-pixels and that protrude in a direction crossing the first direction DR1 between the light emitting areas (EMA1 to EMA7 . . . ). Each of the protruding patterns (PT1 to PT13, . . . ) may include a metal pattern and a dummy pattern protruding from the metal pattern. The protruding direction of the metal patterns may be the same as the protruding direction of the dummy patterns connected to the metal patterns. For example, as described with reference to FIG. 11, each of the metal patterns (UR1 to UR13, . . . ) may have a ring shape. Various shapes of the dummy patterns will be described later with reference to FIG. 16 and FIG. 18.

The metal lines (JHL1a, JHL2a, JHL3a, . . . ) may include first metal lines (JHL1a, JHL3a, . . . ) and second metal lines (JHL2a, . . . ). The first metal lines (JHL1a, JHL3a, . . . ) and the second metal lines (JHL2a, . . . ) may be alternately arranged in the second direction DR2. According to some embodiments, the first metal lines (JHL1a, JHL3a, . . . ) and the second metal lines (JHL2a, . . . ) may have shapes that are symmetrical to each other with respect to the second direction DR2. For example, each of the protruding patterns (PT1 to PT13, . . . ) of the first metal lines (JHL1a, JHL3a, . . . ) may protrude to face the adjacent protruding pattern of the adjacent second metal line. For example, each of the metal patterns of the first metal lines (JHL1a, JHL3a, . . . ) may protrude to face the adjacent metal pattern of the adjacent second metal line. For example, each of the dummy patterns of the first metal lines (JHL1a, JHL3a, . . . ) may protrude to face the adjacent dummy pattern of the adjacent second metal line.

Each of the metal lines (JHL1a, JHL2a, JHL3a, . . . ) may include the protruding patterns (PT1 to PT13, . . . ) that protrude alternately in the second direction DR2 and in a direction opposite to the second direction DR2. For example, the metal patterns and the dummy patterns may protrude in the second direction DR2 or in a direction opposite to the second direction DR2 between the light emitting areas (EMA1 to EMA7, . . . ).

For example, the first metal line JHL1a may sequentially include the first protruding pattern PT1 protruding in the second direction DR2, the second protruding pattern PT2 protruding in a direction opposite to the second direction DR2, the third protruding pattern PT3 protruding in the second direction DR2, the fourth protruding pattern PT4 protruding in a direction opposite to the second direction DR2, and the fifth protruding pattern PT5 protruding in the second direction DR2, along the first direction DR1. The first light emitting area EMA1 may be arranged in the second direction DR2 from the second protruding pattern PT2. The second light emitting area EMA2 may be arranged in the second direction DR2 from the fourth protruding pattern PT4.

Each of the metal lines (JHL1a, JHL2a, JHL3a, . . . ) may further include line patterns (LP1 to LP10, . . . ) that connect the protruding patterns (PT1 to PT13, . . . ) (or metal patterns). For example, the first metal line JHL1a may include a first line pattern LP1 connecting the first protruding pattern PT1 and the second protruding pattern PT2, a second line pattern LP2 connecting the second protruding pattern PT2 and the third protruding pattern PT3, a third line pattern LP3 connecting the third protruding pattern PT3 and the fourth protruding pattern PT4, and a fourth line pattern LP4 connecting the fourth protruding pattern PT4 and the fifth protruding pattern PT5.

The line patterns (LP1 to LP10, . . . ) may have an inclined shape in a plan view to correspond to the outer periphery of the adjacent light emitting areas (EMA1 to EMA7, . . . ). For example, the first line pattern LP1 and the third line pattern LP3 may be parallel to each other. For example, the first line pattern LP1 and the third line pattern LP3 may extend in a direction between a direction opposite to the second direction DR2 and the first direction DR1. The second line pattern LP2 and the fourth line pattern LP4 may be parallel to each other. For example, the second line pattern LP2 and the fourth line pattern LP4 may extend in a direction between the second direction DR2 and the first direction DR1. Accordingly, the first line pattern LP1 and the second line pattern LP2 may not be parallel to each other.

The second metal line JHL2a may sequentially include the sixth protruding pattern PT6 protruding in a direction opposite to the second direction DR2, the seventh protruding pattern PT7 protruding in the second direction DR2, the eighth protruding pattern PT8 protruding in a direction opposite to the second direction DR2, the ninth protruding pattern PT9 protruding in the second direction DR2, and the tenth protruding pattern PT10 protruding in a direction opposite to the second direction DR2, along the first direction DR1. The first light emitting area EMA1 may be arranged in a direction opposite to the second direction DR2 from the seventh protruding pattern PT7. The second light emitting area EMA2 may be arranged in a direction opposite to the second direction DR2 from the ninth protruding pattern PT9. The third light emitting area EMA3 may be arranged in the second direction DR2 from the eighth protruding pattern PT8. The protruding pattern (or metal pattern) protruding in the second direction DR2 may face an adjacent protruding pattern (or metal pattern) protruding in a direction opposite to the second direction DR2. For example, the third protruding pattern PT3 and the eighth protruding pattern PT8 may face each other between the first light emitting area EMA1 and the second light emitting area EMA2.

The second metal line JHL2a may include a fifth line pattern LP5 connecting the sixth protruding pattern PT6 and the seventh protruding pattern PT7, a sixth line pattern LP6 connecting the seventh protruding pattern PT7 and the eighth protruding pattern PT8, a seventh line pattern LP7 connecting the eighth protruding pattern PT8 and the ninth protruding pattern PT9, and an eighth line pattern LP8 connecting the ninth protruding pattern PT9 and the tenth protruding pattern PT10.

The third metal line JHL3a may sequentially include the eleventh protruding pattern PT11 protruding in a direction opposite to the second direction DR2, the twelfth protruding pattern PT12 protruding in the second direction DR2, and the thirteenth protruding pattern PT13 protruding in a direction opposite to the second direction DR2, along the first direction DR1. The third light emitting area EMA3 may be arranged in a direction opposite to the second direction DR2 from the twelfth protruding pattern PT12. The eleventh protruding pattern PT11 and the seventh protruding pattern PT7 may face each other in the second direction DR2. The thirteenth protruding pattern PT13 and the ninth protruding pattern PT9 may face each other in the second direction DR2.

The third metal line JHL3a may include a ninth line pattern LP9 connecting the eleventh protruding pattern PT11 and the twelfth protruding pattern PT12, and a tenth line pattern LP10 connecting the twelfth protruding pattern PT12 and the thirteenth protruding pattern PT13.

Lengths of the metal lines (JHL1a, JHL2a, JHL3a, . . . ) may be the same. Accordingly, resistance values of the metal lines (JHL1a, JHL2a, JHL3a, . . . ) may be the same, and heat due to the Joule heating process may be uniformly generated.

FIG. 16 is a drawing for explaining a metal pattern and a dummy pattern of the metal line in FIG. 15.

Referring to FIG. 16, a heat distribution diagram for a third area of interest AOI3 is shown. The third area of interest AOI3 may include the third protruding pattern PT3 and the eighth protruding pattern PT8 facing each other between the first light emitting area EMA1 and the second light emitting area EMA2. The third protruding pattern PT3 may include a third metal pattern UR3 and a third dummy pattern DMP3a protruding from the third metal pattern UR3. The eighth protruding pattern PT8 may include an eighth metal pattern UR8 and an eighth dummy pattern DMP8a protruding from the eighth metal pattern UR8.

For example, widths of the dummy patterns (DMP3a, DMP8a, . . . ) in the first direction DR1 may be smaller than widths of the metal patterns (UR3, UR8, . . . ) in the first direction DR1. Each of the metal patterns (UR3, UR8, . . . ) may have a shape with two or more layers of wires densely packed together. Each of the metal patterns (UR3, UR8, . . . ) may have a ring shape. Each of the dummy patterns (DMP3a, DMP8a, . . . ) may have a line shape. The protruding direction of the metal patterns (UR3, UR8, . . . ) may be the same as the protruding direction of the dummy patterns (DMP3a, DMP8a, . . . ) connected to the metal patterns (UR3, UR8, . . . ). The third metal pattern UR3 protruding in the second direction DR2 may face the adjacent eighth metal pattern UR8 protruding in a direction opposite to the second direction DR2. The third dummy pattern DMP3a protruding in the second direction DR2 may face the adjacent eighth dummy pattern DMP8a protruding in a direction opposite to the second direction DR2.

As described above, when the first voltage is applied to the first metal pad JPD1 and the second voltage is applied to the second metal pad JPD2, a current may flow through the metal lines JHL1 to JHLo, and heat may be generated due to Joule heating (see the description of FIG. 2). In this case, no current flows toward disconnected dummy patterns (DMP3a, DMP8a, . . . ), and only thermal conduction occurs in the dummy patterns (DMP3a, DMP8a, . . . ).

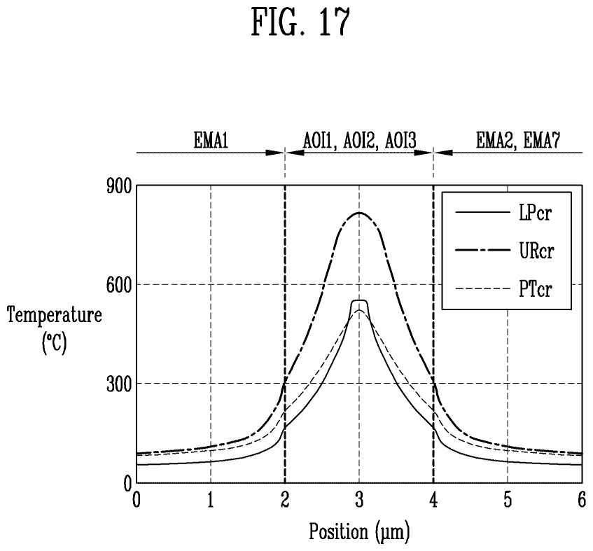

FIG. 17 illustrates temperature graphs of areas of interest in FIG. 12, FIG. 13, and FIG. 16.

Referring to FIG. 17, it can be seen that the temperature of the virtual line PTcr of the third area of interest AOI3 is smaller than the temperature of the virtual line URcr of the first area of interest AOI1. For example, it can be seen that the temperature of the virtual line PTcr of the third area of interest AOI3 is similar to the temperature of the virtual line LPcr of the second area of interest AOI2. That is, according to the embodiments of FIG. 15 and FIG. 16, while lowering the risk that the organic materials of the light emitting areas EMA1 and EMA2 may be sublimated, it is possible to stably sublimate up to the organic material portion not covered by the first metal line JHL1a and the second metal line JHL2a.

FIG. 18 a drawing for explaining various embodiments of dummy patterns.

First to third cases Case1, Case2, and Case3 are cases in which widths of the dummy patterns in the first direction DR1 are the same and lengths thereof in the second direction DR2 are different. In this case, widths of the dummy patterns in the first direction DR1 may be smaller than widths of the connected metal patterns in the first direction DR1.

Fourth to sixth cases Case4, Case5, and Case6 are cases in which widths of the dummy patterns in the first direction DR1 are different and lengths thereof in the second direction DR2 are the same. In the case of the fourth case Case4 and the fifth case Case5, widths of the dummy patterns in the first direction DR1 may be smaller than widths of the connected metal patterns in the first direction DR1. In the case of the sixth case Case6, widths of the dummy patterns in the first direction DR1 may be the same as widths of the metal patterns in the first direction DR1.

Seventh to ninth cases Case7, Case8, and Case9 are cases in which positions of the dummy patterns in the first direction DR1 are different. In the seventh case Case 7, the dummy pattern protruding in the second direction DR2 may face an adjacent dummy pattern protruding in a direction opposite to the second direction DR2. In the eighth and ninth cases Case8 and Case9, the dummy pattern protruding in the second direction DR2 may face the adjacent metal pattern protruding in the opposite direction of the second direction DR2, but may not face the adjacent dummy pattern connected to the adjacent metal pattern. Referring to the eighth and ninth cases Case8 and Case9, lengths of the dummy patterns in the second direction DR2 may vary.

Referring to tenth to twelfth cases Case10, Case11, and Case12, widths of the dummy patterns in the first direction DR1 may gradually decrease toward the protruding direction thereof. For example, the dummy patterns may include sub-patterns whose widths in the first direction DR1 gradually decrease toward the protruding direction.

In the case of the tenth case Case 10, center coordinates of the sub-patterns SDP1a, SDP2a, and SDP3a in the first direction DR1 may be the same. In the case of the eleventh case Case 11, center coordinates of the sub-patterns SDP1b, SDP2b, and SDP3b in the first direction DR1 may be different from each other. For example, coordinates on one sides of the sub-patterns SDP1b, SDP2b, and SDP3b may be the same as each other in the first direction DR1. On the other hand, coordinates on the other sides of the sub-patterns SDP1b, SDP2b, and SDP3b may be different from each other in the first direction DR1. The sub-patterns SPD1c, SDP2c, and SPD3c of the twelfth case Case 12 may have a similar shape to the sub-patterns SDP1b, SDP2b, and SDP3b of the eleventh case Case 11. However, a length of the sub-pattern SPD3c of the twelfth case Case 12 in the second direction DR2 may be greater than a length of the sub-pattern SDP3b of the eleventh case Case 11 in the second direction DR2.

Referring to the temperature graphs on the right side of the table of FIG. 18, it may be seen that all of the first to twelfth cases Case1 to Case12 have a shape similar to that of a single line. Accordingly, the dummy patterns may be configured to have various shapes, as shown in FIG. 18.

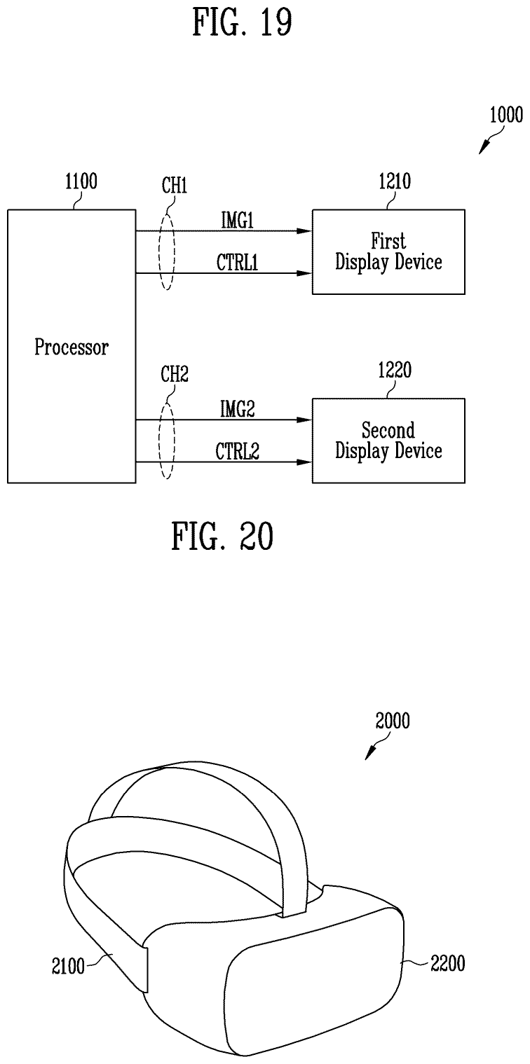

FIG. 19 illustrates a block diagram of a display system according to some embodiments.

Referring to FIG. 19, the display system 1000 may include a processor 1100 and one or more display devices 1210 and 1220.

The processor 1100 may perform various tasks and calculations. According to some embodiments, the processor 1100 may include an application processor, a graphics processor, a microprocessor, a central processing unit (CPU), and the like. The processor 1100 may be connected to and step other constituent elements of the display system 1000 through a bus system.

In FIG. 19, the display system 1000 is shown to include the first and second display devices 1210 and 1220. The processor 1100 may be connected to the first display device 1210 through a first channel CH1 and to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 1000 may include a computing system providing image display functions such as a portable computer, a mobile phone, a smart phone, a tablet personal computer (PC), a smart watch, a watch phone, a portable multimedia player (PMP), a navigation system, and a ultra mobile personal computer (UMPC). In addition, the display system 1000 may include at least one of a head-mounted display device (HMD), a virtual reality (VR) device, a mixed reality (MR) device, or an augmented reality (AR) device.

FIG. 20 illustrates a perspective view of an application example of the display system of FIG. 19.

Referring to FIG. 20, the display system 1000 of FIG. 19 may be applied to a head-mounted display device 2000. The head-mounted display device 2000 may be a wearable electronic device that may be worn on the user's head.

The head-mounted display device 2000 may include a head-mounted band 2100 and a display device accommodation case 2200. The head-mounted band 2100 may be connected to the display device accommodation case 2200. The head-mounted band 2100 may include a horizontal band and/or a vertical band for fixing the head-mounted display device 2000 to the user's head. The horizontal band may be configured to surround the side portion of the user's head, and the vertical band may be configured to surround the upper portion of the user's head. However, embodiments are not limited thereto. For example, the head-mounted band 2100 may be implemented in the form of a spectacle frame, a helmet, or the like.

The display device accommodation case 2200 may accommodate the first and second display devices 1210 and 1220 of FIG. 19. The display device accommodation case 2200 may further accommodate the processor 1100 of FIG. 19.

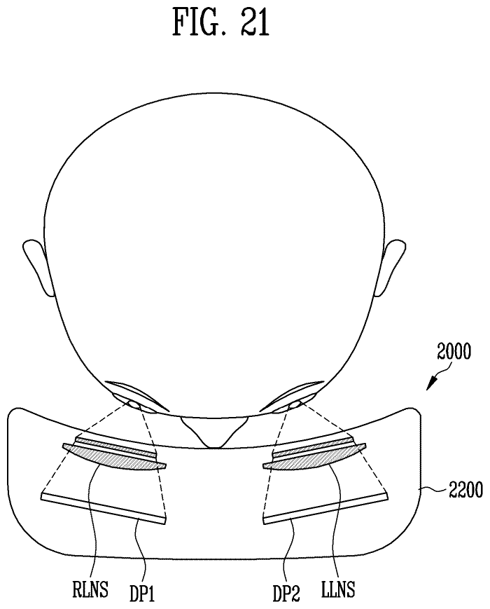

FIG. 21 illustrates a head-mounted display device worn on a user of FIG. 20.

Referring to FIG. 21, a first display panel DP1 of the first display device 1210 and a second display panel DP2 of the second display device 1220 are located in the head mounted display device 2000. The head-mounted display device 2000 may further include one or more lenses LLNS and RLNS.

In the display device accommodation case 2200, the right eye lens RLNS may be located between the first display panel DP1 and the right eye of the user. In the display device accommodation case 2200, the left eye lens LLNS may be located between the second display panel DP2 and the left eye of the user.

An image outputted from the first display panel DP1 may be shown to the right eye of the user through the right eye lens RLNS. The right eye lens RLNS may refract light from the first display panel DP1 to be directed to the right eye of the user. The right eye lens RLNS may perform an optical function to adjust the viewing distance between the first display panel DP1 and the right eye of the user.

An image outputted from the second display panel DP2 may be shown to the left of the user through the left eye lens LLNS. The left eye lens LLNS may refract light from the second display panel DP2 to be directed to the left eye of the user. The left eye lens LLNS may perform an optical function to adjust the viewing distance between the second display panel DP2 and the left eye of the user.

According to some embodiments, each of the right eye lens RLNS and the left eye lens LLNS may include an optical lens having a cross-section of a pancake shape. In the embodiments, each of the right eye lens RLNS and the left eye lens LLNS may include a multi-channel lens including sub-areas with different optical characteristics. In this case, each display panel outputs images corresponding to the sub-areas of the multi-channel lens, and the output images may pass through the sub-areas and be viewed by the user.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims. Therefore, those skilled in the art will understand that various modifications and other equivalent embodiments of the present disclosure are possible. Consequently, the true technical protective scope of the present disclosure must be determined based on the technical spirit of the appended claims, and their equivalents.

What is claimed is:

1. A display device comprising:
a substrate including a non-display area and a display area;
sub-pixels in the display area; and
metal lines crossing the non-display area and the display area in a first direction,
wherein each of the metal lines does not overlap, in a plan view, light emitting areas of the sub-pixels,
each of the metal lines includes metal patterns protruding in a direction crossing the first direction, and
each of the metal lines further includes dummy patterns protruding from the metal patterns.

2. The display device of claim 1, wherein
widths of the dummy patterns in the first direction are smaller than widths of the metal patterns in the first direction.

3. The display device of claim 1, wherein
widths of the dummy patterns in the first direction are equal to widths of the metal patterns in the first direction.

4. The display device of claim 1, wherein
widths of the dummy patterns in the first direction gradually decrease as they protrude in a protruding direction.

5. The display device of claim 1, wherein
each of the metal patterns has a ring shape.

6. The display device of claim 5, wherein
each of the dummy patterns has a line shape.

7. The display device of claim 1, wherein
a protruding direction of the metal patterns and a protruding direction of the dummy patterns connected to the metal patterns are the same.

8. The display device of claim 1, wherein
the metal patterns and the dummy patterns protrude in a second direction crossing the first direction or in a direction opposite to the second direction between the light emitting areas.

9. The display device of claim 8, wherein
a metal pattern protruding in the second direction faces an adjacent metal pattern protruding in a direction opposite to the second direction.

10. The display device of claim 8, wherein
a dummy pattern protruding in the second direction faces an adjacent dummy pattern protruding in a direction opposite to the second direction.

11. The display device of claim 8, wherein
a dummy pattern protruding in the second direction faces an adjacent metal pattern protruding in a direction opposite to the second direction, while it does not face an adjacent dummy pattern connected to the adjacent metal pattern.

12. The display device of claim 1, wherein
the metal lines include first metal lines and second metal lines,
the first metal lines and the second metal lines are alternately arranged in the second direction, and
with respect to the second direction, the first metal lines have a shape symmetrical to the second metal lines.

13. The display device of claim 12, wherein
each of the metal patterns of the first metal lines protrudes to face an adjacent metal pattern of an adjacent second metal line.

14. The display device of claim 1, wherein
each of the metal lines further includes line patterns connecting the metal patterns.

15. The display device of claim 14, wherein
the line patterns have a shape inclined, in the plan view, to correspond to an outer periphery of the light emitting areas adjacent thereto.

16. The display device of claim 1, further comprising
a first metal pad in the non-display area; and
a second metal pad in the non-display area and arranged in the first direction from the first metal pad,
wherein the display area is between the first metal pad and the second metal pad, and
the metal lines connect the first metal pad and the second metal pad.

17. The display device of claim 16, further comprising
data lines extending in a second direction crossing the first direction and connected to the sub-pixels; and
pads connected to the data lines.

18. A wearable device comprising:
a first display panel; and
a second display panel,
wherein each of the first display panel and the second display panel includes
a substrate including a non-display area and a display area;
sub-pixels in the display area; and
metal lines crossing the non-display area and the display area in a first direction, and
each of the metal lines does not overlap, in a plan view, light emitting areas of the sub-pixels,
each of the metal lines includes metal patterns protruding in a direction crossing the first direction, and
each of the metal lines further includes dummy patterns protruding from the metal patterns.

19. The wearable device of claim 18, wherein
widths of the dummy patterns in the first direction are smaller than or equal to widths of the metal patterns in the first direction.

20. The wearable device of claim 18, wherein
each of the metal patterns has a ring shape, and
each of the dummy patterns has a line shape.
